(19) United States
(12) Patent Application Publication
(10) Pub. No.: US 2026/0059904 A1
(43) Pub. Date: Feb. 26, 2026

(54) DISPLAY DEVICE ELECTRODE CONFIGURATIONS

(71) Applicant: Samsung Display Co., Ltd., Yongin-si (KR)

(72) Inventors: Su Mi MOON, Suwon-si (KR); Sin Chul KANG, Hwaseong-Si (KR)

(21) Appl. No.: 19/378,116

(22) Filed: Nov. 3, 2025

Related U.S. Application Data
(63) Continuation of application No. 17/775,077.

(30) Foreign Application Priority Data
Nov. 7, 2019 (KR) 10-2019-0141578

(51) Int. Cl. H10H 20/831; H10H 20/857; H10H 29/14

(52) U.S. Cl. CPC H10H 20/8316; H10H 20/857; H10H 29/142

(57) ABSTRACT

A display device is provided. The display device comprises: a substrate; a first inner bank and a second inner bank disposed so as to be spaced apart from each other on the substrate; a first electrode disposed on a portion of the first inner bank; a second electrode disposed so as to cover the second inner bank; and a light-emitting element disposed between the first electrode and the second electrode, wherein one end portion of the light-emitting element is non-overlapped with the first electrode in a thickness direction, and the other end portion of the light-emitting element is overlapped with the second electrode in a thickness direction.

### CROSS-REFERENCE TO RELATED APPLICATION(S)

This application is a continuation of U.S. patent application Ser. No. 17/775,077, filed on Sep. 4, 2020, which is a national entry of International Application No. PCT/KR2020/011904, filed on Sep. 4, 2020, which claims under 35 U.S.C. 119(a) and 365(b) priority to and benefits of Korean Patent Application No. 10-2019-0141578, filed on Nov. 7, 2019 in the Korean Intellectual Property Office, the entire contents of which are herein incorporated by reference.

### BACKGROUND

### 1. Field

The disclosure relates to a display device.

### 2. Description of the Related Art

The importance of display devices has steadily increased with the development of multimedia technology. In response thereto, various types of display devices such as an organic light-emitting display (OLED), a liquid crystal display (LCD) and the like have been used.

A display device is a device for displaying an image, and may include a display panel, such as an organic light-emitting display panel or a liquid crystal display panel. The light-emitting display panel may include light-emitting elements, e.g., light-emitting diodes (LED), and examples of the light-emitting diode include an organic light-emitting diode (OLED) using an organic material as a fluorescent material and an inorganic light-emitting diode using an inorganic material as a fluorescent material.

### SUMMARY

Aspects of the disclosure provide a display device including electrodes that may have different widths and light-emitting elements disposed between the electrodes.

Aspects of the disclosure also provide a display device in which a separation distance between the electrodes may be greater than a separation distance between an electrode and a voltage line.

It should be noted that aspects of the disclosure are not limited thereto and other aspects, which are not mentioned herein, will be apparent to those of ordinary skill in the art from the following description.

According to one or more embodiments of the disclosure, a display device may include a first inner bank and a second inner bank that are disposed on a substrate and spaced apart from each other, a first electrode disposed on a partial area of the first inner bank and a second electrode covering the second inner bank, and a light-emitting element between the first electrode and the second electrode, wherein an end portion of the light-emitting element may not overlap the first electrode in a thickness direction of the substrate, and another end portion of the light-emitting element overlaps the second electrode in the thickness direction.

The display device may further include a first contact electrode in electrical contact with the first electrode and the end portion of the light-emitting element, and a second contact electrode in electrical contact with the second electrode and the another end portion of the light-emitting element.

The end portion of the light-emitting element may overlap the first contact electrode in the thickness direction, and the another end portion of the light-emitting element may overlap the second contact electrode in the thickness direction.

A separation distance between the first electrode and the second electrode may be greater than a separation distance between the first inner bank and the second inner bank.

The first inner bank may include a side and another side that faces the second inner bank, and the first electrode may cover only the side of the first inner bank.

The second electrode may cover a side of the second inner bank which faces the first inner bank, and another side of the second inner bank.

The display device may further include at least one third inner bank between the first inner bank and the second inner bank, and at least one third electrode between the first electrode and the second electrode, wherein the third electrode may be disposed on a partial area of the third inner bank.

The third inner bank may include a side facing the first inner bank and another side facing the second inner bank, and the third electrode may cover only the side of the third inner bank.

The display device may further include a third contact electrode disposed on the third electrode, wherein a width of the third contact electrode measured in a direction may be greater than a width of the third electrode measured in the direction.

The third contact electrode may be in electrical contact with a light-emitting element between the first electrode and the third electrode and a light-emitting element between the third electrode and the second electrode.

The display device may further include a first voltage line disposed on the substrate, and a first insulating layer covering the first voltage line, wherein the first inner bank and the second inner bank may be disposed directly on the first insulating layer.

At least a partial area of the first voltage line may overlap the first inner bank in the thickness direction, and a separation distance between the second electrode and the first electrode may be greater than a separation distance between the second electrode and the first voltage line.

The first inner bank may include a side on which the first electrode may be disposed, and another side on which the first electrode may not be disposed and which overlaps the first voltage line in the thickness direction.

The display device may further include a second insulating layer covering the another side of the first inner bank and a side of the second electrode, which faces the first electrode, wherein the light-emitting element may be disposed on the second insulating layer.

According to one or more embodiments of the disclosure, a display device may include a data conductive layer disposed on a substrate and including a first voltage line, a first insulating layer covering the data conductive layer, a first electrode and a second electrode disposed on the first insulating layer and spaced apart from each other and facing each other, and a light-emitting element between the first electrode and the second electrode, wherein a vertical distance between the first electrode and the second electrode may be greater than a vertical distance between the second electrode and the first voltage line.

The display device may further include a first inner bank disposed on the first insulating layer, and a second inner bank that may be spaced apart from and face the first inner bank, wherein the first electrode may cover a side of the first inner bank, and the second electrode may cover a side of the second inner bank, which faces the first inner bank, and another side thereof.

The first voltage line may overlap another side of the first inner bank, which faces the second inner bank, in a thickness direction.

The display device may further include a first contact electrode in electrical contact with the first electrode and an end portion of the light-emitting element, and a second contact electrode in electrical contact with the second electrode and another end portion of the light-emitting element, wherein the end portion of the light-emitting element may not overlap the first electrode in the thickness direction, and the another end portion of the light-emitting element may overlap the second electrode in the thickness direction.

The data conductive layer may further include a second voltage line, the first voltage line may be electrically connected to the first electrode, and the second voltage line may be electrically connected to the second electrode.

The display device may further include a third electrode between the first electrode and the second electrode, and a third voltage line between the first voltage line and the second voltage line, wherein a vertical distance between the second electrode and the third electrode may be greater than a vertical distance between the second electrode and the third voltage line.

The details of other embodiments are included in the detailed description and the accompanying drawings.

A display device according to one or more embodiments may include electrodes having different widths, and a separation distance between the electrodes can be greater than a separation distance between a voltage line to which an alignment signal may be applied and an electrode. During a manufacturing process of the display device, an intensity of an electric field formed between the electrode and the voltage line may be greater than an intensity of an electric field formed between the electrodes, and light-emitting elements can be disposed between the electrodes using a stronger electric field.

Accordingly, in a display device according to one or more embodiments, light-emitting elements can be disposed between electrodes with a high degree of alignment.

The effects according to the embodiments are not limited by the above, and additional effects are included in this disclosure.

### BRIEF DESCRIPTION OF THE DRAWINGS

FIG. 1 is a schematic plan view of a display device according to one or more embodiments.

FIG. 2 is a schematic plan view illustrating a pixel of the display device according to one or more embodiments.

FIG. 3 is a schematic cross-sectional view taken along line I-I′ of FIG. 2.

FIG. 4 is a schematic view of a light-emitting element according to one or more embodiments.

FIG. 5 is a schematic cross-sectional view illustrating a portion of a manufacturing process of the display device according to one or more embodiments.

FIG. 6 is a schematic plan view illustrating a portion of a manufacturing process of a display device according to one or more embodiments.

FIGS. 7 and 8 are schematic cross-sectional views illustrating a portion of a manufacturing process of the display device according to one or more embodiments.

FIG. 9 is a schematic plan view illustrating a portion of a manufacturing process of the display device according to one or more embodiments.

FIGS. 10 to 15 are schematic cross-sectional views illustrating a portion of a manufacturing process of the display device according to one or more embodiments.

FIG. 16 is a schematic cross-sectional view illustrating a portion of a display device according to one or more other embodiments.

FIGS. 17 and 18 are schematic cross-sectional views illustrating a portion of a manufacturing process of the display device of FIG. 16.

FIG. 19 is a schematic plan view illustrating a sub-pixel of a display device according to still one or more other embodiments.

FIG. 20 is a schematic cross-sectional view illustrating a portion of the display device of FIG. 19.

FIGS. 21 to 26 are schematic cross-sectional views and plan views illustrating a portion of a manufacturing process of the display device of FIG. 19.

FIG. 27 is a schematic plan view illustrating a sub-pixel of a display device according to yet one or more other embodiments.

FIG. 28 is a schematic plan view illustrating a sub-pixel of a display device according to yet one or more other embodiments.

FIG. 29 is a schematic plan view illustrating a sub-pixel of a display device according to yet one or more other embodiments.

FIG. 30 is a schematic cross-sectional view taken along line II-IF of FIG. 29.

### DETAILED DESCRIPTION

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of meaning and interpretation. For example, “at least one of A and B” may be understood to mean “A, B, or A and B.”

It will be understood that when a layer is referred to as being “on” another layer or substrate, it can be directly on the other layer or substrate, or intervening layers may also be present. The same reference numbers indicate the same components throughout the specification.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

Also, when an element is referred to as being “in contact” or “contacted” or the like to another element, the element may be in “electrical contact” or in “physical contact” with another element; or in “indirect contact” or in “direct contact” with another element.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

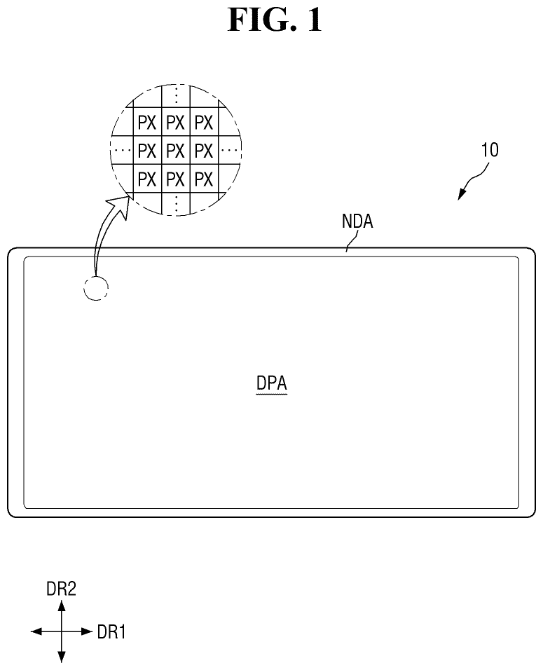

FIG. 1 is a schematic plan view of a display device according to one or more embodiments.

Referring to FIG. 1, a display device 10 may display a video or a still image. The display device 10 may refer to all electronic devices that provide a display screen. For example, the display device 10 may be a television, a notebook, a monitor, an advertising board, an Internet of Things (IoT) device, a mobile phone, a smart phone, a tablet personal computer (PC), an electronic watch, a smart watch, a watch phone, a head mounted display, a mobile communication terminal, an electronic organizer, an electronic book reader, a portable multimedia player (PMP), a navigation device, a game machine, a digital camera, a camcorder, or the like, which provide display screens.

The display device 10 may include a display panel that provides a display screen. Examples of the display panel may include a light-emitting diode (LED) display panel, an organic light-emitting display panel, a quantum dot light-emitting display panel, a plasma display panel, a field emission display panel, and the like. Hereinafter, although an example in which the LED display panel is described, the disclosure is not limited thereto, and the disclosure may be applied to other types of display panels in keeping with same technical spirit.

A shape of the display device 10 may be variously modified. For example, the display device 10 may have shapes such as a rectangular shape of which lateral sides are long, a rectangular shape of which longitudinal sides are long, a square shape, a quadrangular shape of which corner portions (vertexes) are round, other polygonal shapes, a circular shape, and the like. A shape of a display area DPA of the display device 10 may also be similar to the overall shape of the display device 10. In FIG. 1, the display device 10 and the display area DPA, which have a rectangular shape of which lateral sides are long, are illustrated.

The display device 10 may include the display area DPA and a non-display area NDA. The display area DPA may be an area in which an image may be displayed, and the non-display area NDA is an area in which an image may not be displayed. The display area DPA may refer to an active area and the non-display area NDA may refer to an inactive area. The display area DPA may generally occupy a center of the display device 10.

The display area DPA may include pixels PX. The pixels PX may be disposed in a matrix shape. A shape of each of the pixels PX may be a rectangular shape or a square shape in a plan view, but the disclosure is not limited thereto, and the shape may be a rhombus shape of which each side may be inclined with respect to a direction. The pixels PX may be alternately disposed in a stripe type or a PenTile® type. Each of the pixels PX may include one or more light-emitting elements 300 that emit light in a specific wavelength range, thereby displaying a specific color.

The non-display area NDA may be disposed around the display area DPA. The non-display area NDA may completely or partially surround the display area DPA. The display area DPA may have a rectangular shape, and the non-display area NDA may be disposed adjacent to four sides of the display area DPA. The non-display area NDA may constitute a bezel of the display device 10.

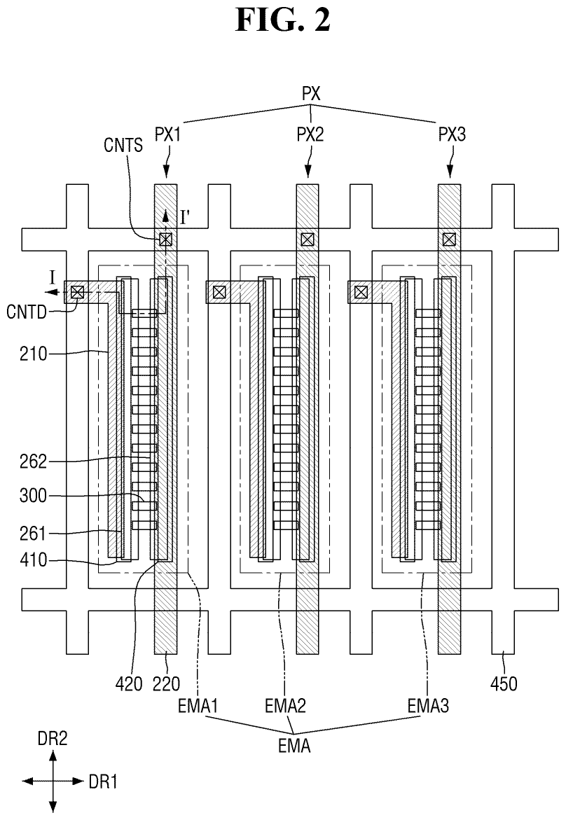

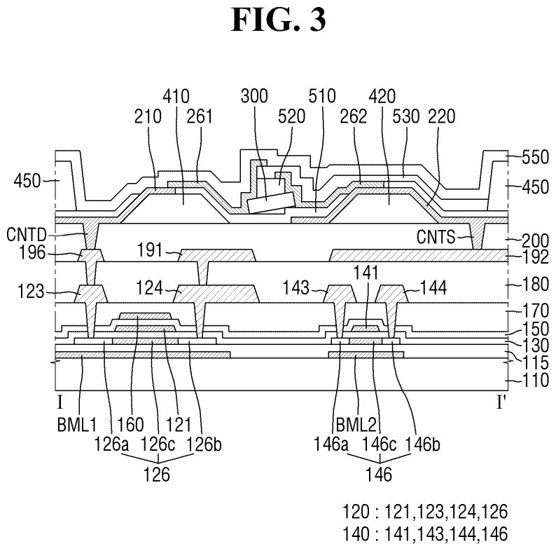

FIG. 2 is a schematic plan view illustrating a pixel of the display device according to one or more embodiments. FIG. 3 is a schematic cross-sectional view taken along line I-I′ of FIG. 2.

Referring to FIGS. 2 and 3, each of the pixels PX may include a first sub-pixel PX1, a second sub-pixel PX2, and a third sub-pixel PX3. The first sub-pixel PX1 may emit light of a first color, the second sub-pixel PX2 may emit light of a second color, and the third sub-pixel PX3 may emit light of a third color. The first color may be blue, the second color may be green, and the third color may be red. However, the disclosure is not limited thereto, and the sub-pixels PXn may emit light having the same color. In FIG. 2, the pixel PX is illustrated as including three sub-pixels PXn, but is not limited thereto, and may include a larger number of sub-pixels PXn.

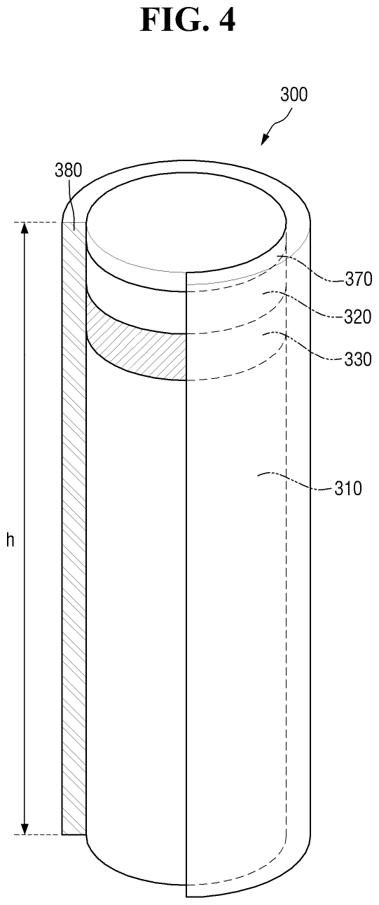

Each of the sub-pixels PXn of the display device 10 may include an area defined as a light-emitting area EMA. The first sub-pixel PX1 may include a first light-emitting area EMA1, the second sub-pixel PX2 may include a second light-emitting area EMA2, and the third sub-pixel PX3 may include a third light-emitting area EMA3. The light-emitting area EMA may be defined as an area in which the light-emitting element 300 included in the display device 10 is disposed to emit light in a specific wavelength range. The light-emitting element 300 may include an active layer 330 (see FIG. 4), and the active layer 330 may emit light in a specific wavelength range without directivity. The light emitted from the active layer 330 of the light-emitting element 300 may also be emitted in directions toward side surfaces of the light-emitting element 300 including both end portions thereof. The light-emitting area EMA may include an area in which the light-emitting element 300 may be disposed, and may include an area which is adjacent to the light-emitting element 300 and through which the light emitted from the light-emitting element 300 may be emitted.

Further, the disclosure is not limited thereto, and the light-emitting area EMA may also include an area in which light emitted from the light-emitting element 300 may be reflected or refracted due to another member to be emitted. Multiple light-emitting elements 300 may be disposed in each sub-pixel PXn, and the area in which the light-emitting elements 300 are disposed and an area adjacent to the area may form the light-emitting area EMA.

Although not shown in the drawing, each of the sub-pixels PXn of the display device 10 may include a non-light-emitting area which may be defined as an area except for the light-emitting area EMA. The non-light-emitting area may be an area in which the light-emitting elements 300 may not be disposed and light emitted from the light-emitting elements 300 may not reach so that light may not be emitted.

FIG. 3 illustrates only a cross section of the first sub-pixel PX1 of FIG. 2, but the cross section may be identically applied to other pixels PX or sub-pixels PXn. FIG. 3 illustrates a cross section traversing an end portion and another end portion of the light-emitting element 300 disposed in the first sub-pixel PX1 of FIG. 2.

The display device 10 may include a circuit element layer and a display element layer disposed on a first substrate 110. A semiconductor layer, conductive layers, and insulating layers are disposed on the first substrate 110. The conductive layers may include a first gate conductive layer, a second gate conductive layer, a first data conductive layer, a second data conductive layer disposed below a first insulating layer 200 to form the circuit element layer, and an electrode and a contact electrode disposed on the first insulating layer 200 to form the display element layer. The insulating layers may include a buffer layer 115, a first gate insulating layer 130, a first protective layer 150, a first interlayer insulating layer 170, a second interlayer insulating layer 180, the first insulating layer 200, a second insulating layer 510, a third insulating layer 520, a fourth insulating layer 530, a fifth insulating layer 550, and the like.

The circuit element layer may include circuit elements and lines for driving the light-emitting element 300, such as a first transistor 120, a second transistor 140, conductive lines 191 and 192, and a conductive pattern 196, and the display element layer may include the light-emitting element 300 and include a first electrode 210, a second electrode 220, a first contact electrode 261, a second contact electrode 262, and the like.

The first substrate 110 may be an insulating substrate. The first substrate 110 may be made of an insulating material such as glass, quartz, a polymer resin, or the like, or a combination thereof. The first substrate 110 may be a rigid substrate but may also be a flexible substrate that is bendable, foldable, rollable, and/or the like.

Light-blocking layers BML1 and BML2 may be disposed on the first substrate 110. The light-blocking layers may include a first light-blocking layer BML1 and a second light-blocking layer BML2. The first light-blocking layer BML1 and the second light-blocking layer BML2 may be disposed to respectively overlap a first active material layer 126 of the first transistor 120 and a second active material layer 146 of the second transistor 140. The first and second light-blocking layers BML1 and BML2 may include light-blocking materials to prevent light from being incident on the first and second active material layers 126 and 146. As an example, the first and second light-blocking layers BML1 and BML2 may be made of opaque metal materials that block light from being transmitted. However, the disclosure is not limited thereto, and in some cases, the light-blocking layers BML1 and BML2 may be omitted. Although not shown in the drawing, the first light-blocking layer BML1 may be electrically connected to a first source/drain electrode 123 of the first transistor 120, which will be described below, and the second light-blocking layer BML2 may be electrically connected to a first source/drain electrode 143 of the second transistor 140.

The buffer layer 115 may be entirely disposed on the first substrate 110, including the light-blocking layers BML1 and BML2. The buffer layer 115 may be formed on the first substrate 110 to protect the transistors 120 and 140 of the pixel PX from moisture permeating through the first substrate 110 that may be vulnerable to moisture permeation, and may perform a surface planarization function. The buffer layer 115 may be formed of inorganic layers that are alternately stacked on each other. For example, the buffer layer 115 may be formed of multiple layers in which one or more inorganic layers of a silicon oxide (SiOx) layer, a silicon nitride (SiNx) layer, and silicon oxynitride (SiON) may be alternately stacked on each other.

The semiconductor layer may be disposed on the buffer layer 115. The semiconductor layer may include the first active material layer 126 of the first transistor 120 and the second active material layer 146 of the second transistor 140. The first active material layer 126 and the second active material layer 146 may be disposed to partially overlap gate electrodes 121 and 141 or the like of the first gate conductive layer to be described below.

In one or more embodiments, the semiconductor layer may include polycrystalline silicon, single-crystalline silicon, an oxide semiconductor, and the like, or a combination thereof. The polycrystalline silicon may be formed by crystallizing amorphous silicon. Examples of the crystallization method may include a rapid thermal annealing (RTA) method, a solid phase crystallization (SPC) method, an excimer laser annealing (ELA) method, a metal induced lateral crystallization (MILC) method, a sequential lateral solidification (SLS) method, and the like, or a combination thereof, but the disclosure is not limited thereto. As another example, the first active material layer 126 and the second active material layer 146 may include single-crystalline silicon, low-temperature polycrystalline silicon, amorphous silicon, and the like, or a combination thereof. In case that the semiconductor layer includes polycrystalline silicon, the first active material layer 126 may include a first doped area 126a, a second doped area 126b, and a first channel area 126c. The first channel area 126c may be disposed between the first doped area 126a and the second doped area 126b. The second active material layer 146 may include a third doped area 146a, a fourth doped area 146b, and a second channel area 146c. The second channel area 146c may be disposed between the third doped area 146a and the fourth doped area 146b. The first doped area 126a, the second doped area 126b, the third doped area 146a, and the fourth doped area 146b may be areas in which partial areas of the first active material layer 126 and the second active material layer 146 may be doped with impurities.

However, the first active material layer 126 and the second active material layer 146 are not necessarily limited to the above description. In one or more embodiments, the first active material layer 126 and the second active material layer 146 may include an oxide semiconductor. In this case, the first doped area 126a and the third doped area 146a may be first conductive areas, and the second doped area 126b and the fourth doped area 146b may be second conductive areas. In case that the first active material layer 126 and the second active material layer 146 include an oxide semiconductor, the oxide semiconductor may be an oxide semiconductor containing indium (In). In some embodiments, the oxide semiconductor may include indium-tin oxide (ITO), indium-zinc oxide (IZO), indium-gallium oxide (IGO), indium-zinc-tin oxide (IZTO), indium-gallium-tin oxide (IGTO), indium-gallium-zinc-tin oxide (IGZTO), or the like, or a combination thereof. However, the disclosure is not limited thereto.

The first gate insulating layer 130 may be disposed on the semiconductor layer and the buffer layer 115. The first gate insulating layer 130 may be disposed on the buffer layer 115, including the semiconductor layer. The first gate insulating layer 130 may serve as gate insulating films of the first and second transistors 120 and 140. The first gate insulating layer 130 may be made of an inorganic material such as silicon oxide (SiOx), silicon nitride (SiNx), or a stacked structure thereof.

The first gate conductive layer may be disposed on the first gate insulating layer 130. The first gate conductive layer may include the first gate electrode 121 of the first transistor 120 and the second gate electrode 141 of the second transistor 140. The first gate electrode 121 may be disposed to overlap at least a partial area of the first active material layer 126, and the second gate electrode 141 may be disposed to overlap at least a partial area of the second active material layer 146. For example, the first gate electrode 121 may be disposed to overlap the first channel area 126c of the first active material layer 126 in a thickness direction, and the second gate electrode 141 may be disposed to overlap the second channel area 146c of the second active material layer 146 in the thickness direction.

The first gate conductive layer may be formed of a single layer or a multi-layer that is made of at least one of molybdenum (Mo), aluminum (Al), chromium (Cr), gold (Au), titanium (Ti), nickel (Ni), neodymium (Nd), or copper (Cu) or an alloy thereof. However, the disclosure is not limited thereto.

The first protective layer 150 may be disposed on the first gate conductive layer. The first protective layer 150 may be disposed to cover the first gate conductive layer to perform a function of protecting the first gate conductive layer. The first protective layer 150 may be formed of an inorganic material such as silicon oxide (SiOx), silicon nitride (SiNx), or a stacked structure thereof.

The second gate conductive layer may be disposed on the first protective layer 150. The second gate conductive layer may include a first capacitor electrode 160 of a storage capacitor disposed so that at least a partial area thereof overlaps the first gate electrode 121 in the thickness direction. The first capacitor electrode 160 and the first gate electrode 121 may overlap each other in the thickness direction with the first protective layer 150 interposed therebetween, and the storage capacitor may be formed therebetween. The second gate conductive layer may be formed of a single layer or a multi-layer that is made of at least one of molybdenum (Mo), aluminum (Al), chromium (Cr), gold (Au), titanium (Ti), nickel (Ni), neodymium (Nd), or copper (Cu) or an alloy thereof. However, the disclosure is not limited thereto.

The first interlayer insulating layer 170 may be disposed on the second gate conductive layer. The first interlayer insulating layer 170 may serve as an insulating film between the second gate conductive layer and other layers disposed thereon. The first interlayer insulating layer 170 may be made of an inorganic material such as silicon oxide (SiOx), silicon nitride (SiNx), or a stacked structure thereof.

The first data conductive layer may be disposed on the first interlayer insulating layer 170. The first gate conductive layer may include the first source/drain electrode 123 and a second source/drain electrode 124 of the first transistor 120, and the first source/drain electrode 143 and a second source/drain electrode 144 of the second transistor 140.

The first source/drain electrode 123 and the second source/drain electrode 124 of the first transistor 120 may be respectively in contact with the first doped area 126a and the second doped area 126b of the first active material layer 126 through contact holes passing through the first interlayer insulating layer 170 and the first gate insulating layer 130. The first source/drain electrode 143 and the second source/drain electrode 144 of the second transistor 140 may be respectively in contact with the third doped area 146a and the fourth doped area 146b of the second active material layer 146 through contact holes passing through the first interlayer insulating layer 170 and the first gate insulating layer 130. The first source/drain electrode 123 of the first transistor 120 and the first source/drain electrode 143 of the second transistor 140 may be electrically connected to the first light-blocking layer BML1 and the second light-blocking layer BML2, respectively, through other contact holes. In the first source/drain electrodes 123 and 143 and the second source/drain electrodes 124 and 144 of the first transistor 120 and the second transistor 140, in case that an electrode is a source electrode, another electrode may be a drain electrode. However, the disclosure is not limited thereto, and in the first source/drain electrodes 123 and 143 and the second source/drain electrodes 124 and 144, in case that an electrode is a drain electrode, another electrode may be a source electrode.

The first data conductive layer may be formed of a single layer or a multi-layer that is made of at least one of molybdenum (Mo), aluminum (Al), chromium (Cr), gold (Au), titanium (Ti), nickel (Ni), neodymium (Nd), or copper (Cu) or an alloy thereof. However, the disclosure is not limited thereto.

The second interlayer insulating layer 180 may be disposed on the first data conductive layer. The second interlayer insulating layer 180 may be entirely disposed on the first interlayer insulating layer 170 while covering the first data conductive layer and may serve to protect the first data conductive layer. The second interlayer insulating layer 180 may serve as an insulating film between the first data conductive layer and the second data conductive layer disposed thereon. The second interlayer insulating layer 180 may be made of an inorganic material such as silicon oxide (SiOx), silicon nitride (SiNx), or a stacked structure thereof.

The second data conductive layer may be disposed on the second interlayer insulating layer 180. The second data conductive layer may include a first voltage line 191, a second voltage line 192, and a first conductive pattern 196. A high potential voltage (a first power voltage) to be supplied to the first transistor 120 may be applied to the first voltage line 191, and a low potential voltage (a second power voltage) to be supplied to the second electrode 220 to be described below may be applied to the second voltage line 192. The first voltage line 191 and the second voltage line 192 may be used to align the light-emitting elements 300 during a manufacturing process of the display device 10, as will be described below.

The first conductive pattern 196 may be electrically connected to the first source/drain electrode 123 of the first transistor 120 through a contact hole formed in the second interlayer insulating layer 180. The first conductive pattern 196 may also be electrically connected to the first electrode 210, which will be described below, and the first transistor 120 may transmit the first power voltage applied from the first voltage line 191 to the first electrode 210 through the first conductive pattern 196. In the drawing, the second data conductive layer is illustrated as including a first voltage line 191 and a second voltage line 192, but the disclosure is not limited thereto. The second data conductive layer may include a larger number of first voltage lines 191 and a larger number of second voltage lines 192.

The second data conductive layer may be formed of a single layer or a multi-layer that may be made of at least one of molybdenum (Mo), aluminum (Al), chromium (Cr), gold (Au), titanium (Ti), nickel (Ni), neodymium (Nd), or copper (Cu) or an alloy thereof. However, the disclosure is not limited thereto.

The first insulating layer 200 is disposed on the second data conductive layer. The first insulating layer 200 may include an organic insulating material and perform a surface planarization function.

Inner banks 410 and 420, electrodes 210 and 220, an outer bank 450, contact electrodes 261 and 262, and the light-emitting element 300 may be disposed on the first insulating layer 200. Further, insulating layers 510, 520, 530, and 550 may be further disposed on the first insulating layer 200.

The inner banks 410 and 420 may be disposed directly on the first insulating layer 200. The inner banks 410 and 420 may include a first inner bank 410 and a second inner bank 420 disposed adjacent to a center portion of each pixel PX or sub-pixel PXn.

The first inner bank 410 and the second inner bank 420 may be disposed to be spaced apart from each other and face each other in a first direction DR1. The first inner bank 410 and the second inner bank 420 may extend in a second direction DR2, and may be spaced apart from each other and terminated at a boundary between the sub-pixels PXn so as not to extend to another sub-pixel PXn adjacent in the second direction DR2. Accordingly, the first inner bank 410 and the second inner bank 420 may be disposed in each sub-pixel PXn to form a pattern on the entire surface of the display device 10. By disposing the inner banks 410 and 420 to be spaced apart from each other and face each other, an area in which the light-emitting element 300 may be disposed may be formed therebetween. In the drawing, it is illustrated that one first inner bank 410 and one second inner bank 420 may be disposed, but the disclosure is not limited thereto. In some cases, each of the inner banks 410 and 420 may be disposed in plural or a larger number of other inner banks 410 and 420 may be further disposed according to the number of the electrodes 210 and 220, which will be described below.

Further, each of the first inner bank 410 and the second inner bank 420 may have a structure in which at least a portion thereof protrudes with respect to an upper surface of the first planarization layer 180. The protruding portion of each of the first inner bank 410 and the second inner bank 420 may have inclined side surfaces, and light emitted from a light-emitting element 300 disposed between the first inner bank 410 and the second inner bank 420 may travel toward the inclined side surfaces of the inner banks 410 and 420. As will be described below, in case that the electrodes 210 and 220 respectively disposed on the inner banks 410 and 420 include a material having high reflectance, the light emitted from the light-emitting element 300 may be reflected from the side surfaces of the inner banks 410 and 420 to be emitted in an upward direction with respect to the first substrate 110. For example, the inner banks 410 and 420 may provide an area in which the light-emitting element 300 may be disposed and simultaneously may serve as a reflective partition wall that reflects light emitted from the light-emitting element 300 upward. In one or more embodiments, the inner banks 410 and 420 may include an organic insulating material such as polyimide (PI), but the disclosure is not limited thereto.

The electrodes 210 and 220 may be disposed on the inner banks 410 and 420 and the first insulating layer 200. The electrodes 210 and 220 may include the first electrode 210 disposed on the first inner bank 410 and the second electrode 220 disposed on the second inner bank 420.

As shown in FIG. 2, the first electrode 210 may be disposed to extend in the second direction DR2 in each sub-pixel PXn. The first electrode 210 may not extend to another sub-pixel PXn adjacent in the second direction DR2, and may be disposed to be partially spaced apart from the outer bank 450 surrounding each sub-pixel PXn. At least a partial area of the first electrode 210 may be disposed to overlap the outer bank 450, which will be described below, and the first electrode 210 may be electrically connected to the first transistor 120 in the area overlapping the outer bank 450. For example, the first electrode 210 may be in contact with the first conductive pattern 196 through a first electrode contact hole CNTD formed in the area overlapping the outer bank 450 and passing through the first planarization layer 180, and through this, the first electrode 210 may be electrically connected to the first source/drain electrode 123 of the first transistor 120. The first electrodes 210 disposed in each sub-pixel PXn may receive different electrical signals from the respective first transistors 120.

The second electrode 220 may be disposed to extend in the second direction DR2 in each sub-pixel PXn. Unlike the first electrode 210, the second electrode 220 may be disposed to extend to another sub-pixel PXn adjacent in the second direction DR2. For example, the sub-pixels PXn adjacent in the second direction DR2 may share a second electrode 220. The second electrode 220 may partially overlap the outer bank 450 at a boundary of the sub-pixels PXn adjacent in the second direction DR2, and the second electrode 220 may be electrically connected to the second voltage line 192 in an area overlapping the outer bank 450. For example, the second electrode 210 may be in contact with the second voltage line 192 through a second electrode contact hole CNTS formed in an area overlapping the outer bank 450 and passing through the first planarization layer 180. As shown in the drawing, the second electrodes 220 of the sub-pixels PXn adjacent in the first direction DR1 are electrically connected to the second voltage lines 192 through the second electrode contact holes CNTS, respectively, and the second electrodes 220 and the second voltage lines 192 may receive the same electrical signal.

However, the disclosure is not limited thereto. In some cases, the second electrode 220 may further include a stem portion extending in the first direction DR1, and the second electrodes 220 of the sub-pixels PXn adjacent in the first direction DR1 may be electrically connected to each other through the stem portion. In this case, the second electrodes 220 of the sub-pixels PXn may receive the same electrical signal from the second voltage lines 192. In this case, the second electrode 220 may be electrically connected to the second voltage line 192 in the non-display area NDA located at a peripheral portion of the display area DPA in which the pixels PX or sub-pixels PXn may be disposed.

The first electrode 210 and the second electrode 220 may be disposed on the first inner bank 410 and the second inner bank 420, respectively, and may be spaced apart from each other and face each other in the first direction DR1. The light-emitting elements 300 may be disposed between the first inner bank 410 and the second inner bank 420, and the light-emitting element 300 may be disposed between the first electrode 210 and the second electrode 220, and simultaneously, at least one end portion of the light-emitting element 300 may be electrically connected to the first electrode 210 and the second electrode 220.

The electrodes 210 and 220 may be electrically connected to the light-emitting elements 300 and may receive a voltage to allow the light-emitting element 300 to emit light. For example, the electrodes 210 and 220 may be electrically connected to the light-emitting element 300 through the contact electrodes 261 and 262, which will be described below, and may transmit an electrical signal applied to the electrodes 210 and 220 to the light-emitting element 300 through the contact electrodes 261 and 262.

In one or more embodiments, the first electrode 210 may be a pixel electrode separated for each sub-pixel PXn, and the second electrode 220 may be a common electrode connected in common along each sub-pixel PXn. One of the first electrode 210 or the second electrode 220 may be an anode of the light-emitting element 300, and another one thereof may be a cathode of the light-emitting element 300. However, the disclosure is not limited thereto, and the reverse of the above description may be possible.

According to one or more embodiments, the first electrode 210 and the second electrode 220 may be formed to have different widths. For example, a width of the second electrode 220 measured in the first direction DR1 may be formed to be greater than a width of the second inner bank 420 measured in the first direction DR1, and thus the second electrode 220 may be disposed to cover an outer surface of the second inner bank 420. Accordingly, a portion of a lower surface of the second electrode 220 may be in contact with the second inner bank 420, and another portion thereof may be in contact with the first insulating layer 200.

On the other hand, a width of the first electrode 210 measured in the first direction DR1 may be formed to be less than a width of the second electrode 220 measured in the first direction DR1, and thus the first electrode 210 may be formed on the first inner bank 410 such that a portion of an outer surface of the first inner bank 410 is exposed. The first inner bank 410 and the second inner bank 420 may have the same width, and the first electrode 210 may be disposed to cover only a side of the first inner bank 410, for example, a side opposite to another side of the first inner bank 410 facing the second inner bank 420. Accordingly, according to one or more embodiments, a separation distance between the first inner bank 410 and the second inner bank 420 may be less than a separation distance between the first electrode 210 and the second electrode 220.

Each of the electrodes 210 and 220 may be utilized to form an electric field in the sub-pixel PXn, thereby aligning the light-emitting element 300. The light-emitting element 300 may be disposed between the first electrode 210 and the second electrode 220 through a process of forming an electric field between the first electrode 210 and the second electrode 220 by applying an alignment signal to the first electrode 210 and the second electrode 220. As will be described below, the light-emitting element 300 may be sprayed on the first electrode 210 and the second electrode 220 in a state of being dispersed in an ink through an inkjet process, and may be aligned between the first electrode 210 and the second electrode 220 through a method of applying a dielectrophoretic force to the light-emitting element 300 by applying the alignment signal between the first electrode 210 and the second electrode 220. A further detailed description thereof will be provided below with reference to other drawings.

Here, the alignment signal applied to each of the electrodes 210 and 220 may also be simultaneously applied to the second data conductive layer disposed below the first insulating layer 200, for example, the first voltage line 191 and the second voltage line 192. The first electrode 210 and the second electrode 220 are disposed in the same layer, but the first voltage line 191 and the second voltage line 192 of the second data conductive layer are disposed in different layers. Depending on a thickness of the first insulating layer 200 disposed on the second data conductive layer, the electric field may also be formed between the second electrode 220 and the first voltage line 191 in addition to between the second electrode 220 and the first electrode 210. Here, an intensity of the electric field formed between the second electrode 220 and the first voltage line 191 may be higher than an intensity of the electric field formed between the first electrode 210 and the second electrode 220 according to the arrangement of the first voltage line 191. Accordingly, during the manufacturing process of the display device 10, the light-emitting element 300 may receive a dielectrophoretic force with a higher intensity due to the electric field formed between the second electrode 220 and the first voltage line 191 and may be smoothly disposed between the first electrode 210 and the second electrode 220.

In the display device 10 according to one or more embodiments, the first electrode 210 may be disposed to cover only a portion of an upper surface of the first inner bank 410, and a vertical distance between the first electrode 210 and the second electrode 220 may be greater than a vertical distance between the second electrode 220 and the first voltage line 191. In the display device 10, the light-emitting element 300 may be disposed with the electric field of a higher intensity than in case that the light-emitting element 300 is disposed by forming the electric field only between the first electrode 210 and the second electrode 220, and the number of the light-emitting elements 300 disposed between the first electrode 210 and the second electrode 220 may increase. Further, the light-emitting elements 300 may be disposed in a state of being oriented in a direction between the first electrode 210 and the second electrode 220, and the light-emitting elements 300 disposed with a higher intensity may reduce errors in an orientation direction to improve a degree of alignment. A detailed description thereof will be provided below

Each of the electrodes 210 and 220 may include a transparent conductive material. As an example, each of the electrodes 210 and 220 may include materials such as indium tin oxide (ITO), indium zinc oxide (IZO), indium tin-zinc oxide (ITZO), and the like, or a combination thereof, but the disclosure is not limited thereto. In some embodiments, each of the electrodes 210 and 220 may include a conductive material having high reflectance. For example, each of the electrodes 210 and 220 may include a metal such as silver (Ag), copper (Cu), aluminum (Al), or the like, or a combination thereof, as the material having high reflectance. In this case, light incident on each of the electrodes 210 and 220 may be reflected and emitted in an upward direction with respect to each sub-pixel PXn.

Further, each of the electrodes 210 and 220 may be formed in a structure, in which one or more layers of a transparent conductive material and a metal layer having high reflectance are stacked on each other, or formed as a single layer including the transparent conductive material and the metal layer. In one or more embodiments, each of the electrodes 210 and 220 may have a stacked structure of ITO/Ag/ITO/IZO or may be an alloy including Al, Ni, lanthanum (La), and the like. However, the disclosure is not limited thereto.

In the drawing, it is illustrated that one first electrode 210 and one second electrode 220 are disposed in each sub-pixel PXn, but the disclosure is not limited thereto. Like the inner banks 410 and 420, a larger number of the first electrodes 210 and second electrodes 220 may be disposed. Further, the first electrode 210 and the second electrode 220 may not necessarily have a shape extending in a direction and may be disposed in various structures. For example, the first electrode 210 and the second electrode 220 may each have a partially curved or bent shape, and an electrode of the first electrode 210 and the second electrode 220 may be disposed to surround another electrode thereof. As long as at least a partial area of the first electrode 210 and at least a partial area of the second electrode 220 are spaced apart from each other to form an area in which the light-emitting element 300 is to be disposed therebetween, the arrangement structures and shapes of the first electrode 210 and the second electrode 220 are not particularly limited.

The second insulating layer 510 may be disposed on the first insulating layer 200, the first electrode 210, and the second electrode 220. The second insulating layer 510 may also be disposed on a side opposite to the area between the inner banks 410 and 420 with respect to the inner banks 410 and 420 in addition to the area between the electrodes 210 and 220 or between the inner banks 410 and 420 spaced apart from each other. The second insulating layer 510 may be disposed to partially cover the first inner bank 410, the first electrode 210, and the second electrode 220. For example, the second insulating layer 510 may be entirely disposed on the first insulating layer 200, including the first electrode 210 and the second electrode 220, and may be disposed to expose a portion of an upper surface of each of the first electrode 210 and the second electrode 220. For example, an opening (not shown) partially exposing the first electrode 210 and the second electrode 220 may be formed in the second insulating layer 510. Some of the first electrode 210 and the second electrode 220, which are disposed on the inner banks 410 and 420, may be partially exposed due to the opening.

Further, as described above, since the first electrode 210 may be disposed to cover only a side of the first inner bank 410, the second insulating layer 510 may be disposed to cover another side of the first inner bank 410, for example, a side of the first inner bank 410, which may be spaced apart from and faces the second inner bank 420. Accordingly, according to one or more embodiments, at least a partial area of the second insulating layer 510 may be in direct contact with the first inner bank 410. The second insulating layer 510 may be in contact with the first inner bank 410 in the exposed area of the upper surface of the first inner bank 410, in which the first electrode 210 may not disposed.

The second insulating layer 510 may protect the first electrode 210 and the second electrode 220 and, simultaneously, insulate the first electrode 210 from the second electrode 220. The light-emitting element 300 disposed on the second insulating layer 510 may be prevented from being damaged by being in direct contact with other members. However, the shape and structure of the second insulating layer 510 are not limited thereto.

In one or more embodiments, a stepped portion may be formed on a portion of an upper surface of the second insulating layer 510 between the first electrode 210 and the second electrode 220. In some embodiments, the second insulating layer 510 may include an inorganic insulating material, and a portion of the upper surface of the second insulating layer 510 disposed to partially cover the first electrode 210 and the second electrode 220 may be stepped due to the stepped portion that is formed by the electrodes 210 and 220 disposed below the second insulating layer 510. An empty space may be formed between the light-emitting element 300, which may be disposed on the second insulating layer 510 between the first electrode 210 and the second electrode 220, and the upper surface of the second insulating layer 510. The empty space may be filled with a material forming the third insulating layer 520, which will be described below.

The outer bank 450 may be disposed on the second insulating layer 510. As shown in FIGS. 2 and 3, the outer bank 450 may be disposed at a boundary between the sub-pixels PXn. The outer bank 450 may be disposed to extend in the first direction DR1 and the second direction DR2 to surround some of the inner banks 410 and 420 and the electrodes 210 and 220, including the area in which the light-emitting element 300 may be disposed between the inner banks 410 and 420 and between the electrodes 210 and 220. For example, the outer bank 450 may form a grid pattern on the entire surface of the display area DPA.

According to one or more embodiments, a height of the outer bank 450 may be greater than a height of each of the inner banks 410 and 420. Unlike the inner banks 410 and 420, the outer bank 450 may divide adjacent sub-pixels PXn, and simultaneously, prevent the ink from overflowing to the adjacent sub-pixels PXn in the inkjet process for disposing the light-emitting element 300 during the manufacturing process of the display device 10. For example, the outer bank 450 may separate inks in which other light-emitting elements 300 are dispersed for other sub-pixels PXn so as to prevent the inks from being mixed with each other. Like the inner banks 410 and 420, the outer bank 450 may include polyimide (PI), but the disclosure is not limited thereto.

The light-emitting element 300 may be disposed between the first electrode 210 and the second electrode 220, or between the first inner bank 410 and the second inner bank 420. An end portion of the light-emitting element 300 may be electrically connected to the first electrode 210, and another end portion thereof may be electrically connected to the second electrode 220. The light-emitting element 300 may be electrically connected to the first electrode 210 and the second electrode 220 respectively through contact electrodes 261 and 262, which will be described below.

The light-emitting elements 300 may be disposed to be spaced apart from each other and aligned to be substantially parallel to each other. A separation distance between the light-emitting elements 300 is not specifically limited. In some cases, the light-emitting elements 300 may be disposed adjacent to each other to form a group, and other light-emitting elements 300 may be grouped in a state of being spaced apart at an interval and may have a nonuniform density but may be oriented and aligned in a direction. In one or more embodiments, the light-emitting element 300 may have a shape extending in a direction, and a direction in which each electrode, for example, each of the first electrode 210 and the second electrode 220 extends may be substantially perpendicular to a direction in which the light-emitting element 300 extends. However, the disclosure is not limited thereto, and the light-emitting element 300 may be obliquely disposed without being perpendicular to the direction in which each of the electrodes extends.

The light-emitting elements 300 according to one or more embodiments may include active layers 330 having different materials to emit light in different wavelength ranges to the outside. The display device 10 according to one or more embodiments may include the light-emitting elements 300 emitting light in different wavelength ranges. The light-emitting element 300 of the first sub-pixel PX1 may include an active layer 330 that emits first light having a first wavelength at a central wavelength band, the light-emitting element 300 of the second sub-pixel PX2 may include an active layer 330 that emits second light having a second wavelength at a central wavelength band, and the light-emitting element 300 of the third sub-pixel PX3 may include an active layer 330 that emits third light having a third wavelength at a central wavelength band.

Thus, the first light may be emitted from the first sub-pixel PX1, the second light may be emitted from the second sub-pixel PX2, and the third light may be emitted from the third sub-pixel PX3. In some embodiments, the first light may be blue light having a central wavelength band ranging from 450 nm to 495 nm, the second light may be green light having a central wavelength band ranging from 495 nm to 570 nm, and the third light may be red light having a central wavelength band ranging from 620 nm to 752 nm.

However, the disclosure is not limited thereto. In some cases, the first sub-pixel PX1, the second sub-pixel PX2, and the third sub-pixel PX3 may include the same type of light-emitting elements 300 to emit light of substantially the same color.

The light-emitting element 300 may be disposed on the second insulating layer 510 between the electrodes 210 and 220. For example, the light-emitting element 300 may be disposed on the second insulating layer 510 disposed between the inner banks 410 and 420. However, the disclosure is not limited thereto, and although not shown in the drawing, at least some of the light-emitting elements 300 disposed in each sub-pixel PXn may be disposed at areas other than an area formed between the inner banks 410 and 420, for example, areas between the inner banks 410 and 420 and the outer bank 450. The light-emitting element 300 may be disposed such that a partial area thereof overlaps each of the electrodes 210 and 220 in the thickness direction. As described above, in the display device 10 according to one or more embodiments, since the first electrode 210 may be disposed to cover only a side of the first inner bank 410, an end portion of the light-emitting element 300 may not overlap the first electrode 210 in the thickness direction, and another end portion thereof overlaps the second electrode 220 in the thickness direction to be placed on the second electrode 220.

Although not shown in the drawing, in the light-emitting element 300, layers may be disposed in a direction parallel to an upper surface of the first substrate 110 or the first insulating layer 200. The light-emitting element 300 of the display device 10 according to one or more embodiments may have a shape extending in a direction and have a structure in which semiconductor layers are sequentially disposed in a direction. The light-emitting element 300 may be disposed such that a direction, in which the light-emitting element 300 extends, may be parallel to the first insulating layer 200, and the semiconductor layers included in the light-emitting element 300 may be sequentially disposed in the direction parallel to the upper surface of the first insulating layer 200. However, the disclosure is not limited thereto. In some cases, in case that the light-emitting element 300 has a different structure, the plurality of layers may be disposed in a direction perpendicular to the first insulating layer 200. A detailed description of the structure of the light-emitting element 300 will be provided below with reference to other drawings.

The third insulating layer 520 may be partially disposed on the light-emitting element 300 disposed between the first electrode 210 and the second electrode 220. For example, the third insulating layer 520 may be disposed to partially surround an outer surface of the light-emitting element 300 and thus may protect the light-emitting element 300 and may also serve to fix the light-emitting element 300 during the manufacturing process of the display device 10. A portion of the third insulating layer 520 disposed on the light-emitting element 300 may have a shape extending in the second direction DR2 between the first electrode 210 and the second electrode 220 in a plan view. As an example, the third insulating layer 520 may form a stripe or island type pattern in each sub-pixel PXn.

According to one or more embodiments, the third insulating layer 520 may be disposed on the light-emitting element 300 and may expose an end portion and another end portion of the light-emitting element 300. The exposed end portion of the light-emitting element 300 may be in contact with the contact electrodes 261 and 262, which will be described below. Such a shape of the third insulating layer 520 may be formed by a patterning process using a material forming the third insulating layer 520 by using a typical mask process. A mask for forming the third insulating layer 520 has a width less than a length of the light-emitting element 300, and the material forming the third insulating layer 520 may be patterned to expose both end portions of the light-emitting element 300. However, the disclosure is not limited thereto.

Further, in one or more embodiments, a portion of the material of the third insulating layer 520 may be disposed between the second insulating layer 510 and a lower surface of the light-emitting element 300. The third insulating layer 520 may be formed to fill a space between the second insulating layer 510 and the light-emitting element 300, which may be formed during the manufacturing process of the display device 10. Accordingly, the third insulating layer 520 may be formed to surround the outer surface of the light-emitting element 300. However, the disclosure is not limited thereto.

The contact electrodes 261 and 262 and the fourth insulating layer 530 may be disposed on the third insulating layer 520.

As shown in FIG. 2, the contact electrodes 261 and 262 may each have a shape extending in a direction. The contact electrodes 261 and 262 may be in contact with the electrodes 210 and 220, respectively, and the light-emitting element 300, and the light-emitting elements 300 may receive electrical signals from the first electrode 210 and the second electrode 220 through the contact electrodes 261 and 262.

The contact electrodes 261 and 262 may include the first contact electrode 261 and the second contact electrode 262. The first contact electrode 261 and the second contact electrode 262 may be disposed in partial areas of the first electrode 210 and the second electrode 220, respectively. The first contact electrode 261 may be disposed on the first electrode 210, the second contact electrode 262 may be disposed on the second electrode 220, and the first contact electrode 261 and the second contact electrode 262 may each have a shape extending in the second direction DR2. The first contact electrode 261 and the second contact electrode 262 may be spaced apart from each other and face each other in the first direction DR1, and may form a stripe pattern in the light-emitting area EMA of each sub-pixel PXn.

In some embodiments, a width of each of the first contact electrode 261 and the second contact electrode 262, which may be measured in a direction, may be smaller than a width of each of the first electrode 210 and the second electrode 220 or a second electrode branch portion, which may be measured in the direction. The first contact electrode 261 and the second contact electrode 262 may be disposed to be in contact with an end portion and another end portion of the light-emitting element 300, respectively, and simultaneously, to be partially in contact with the upper surfaces of the first electrode 210 and the second electrode 220, respectively. As described above, the upper surface of each of the first electrode 210 and the second electrode 220 may be partially exposed, and the first contact electrode 261 and the second contact electrode 262 may be in contact with the exposed upper surfaces of the first electrode 210 and the second electrode 220, respectively. For example, the first contact electrode 261 may be in contact with a portion of the first electrode 210, which may be located on the first inner bank 410, and the second contact electrode 262 may be in contact with a portion of the second electrode 220, which may be located on the second inner bank 420. However, the disclosure is not limited thereto, and in some cases, the first contact electrode 261 and the second contact electrode 262 may be disposed to entirely cover the upper surfaces of the first electrode 210 and the second electrode 220, respectively.

As shown in FIG. 3, the second contact electrode 262 is disposed on the second electrode 220 and the second insulating layer 510. The second contact electrode 262 may be in contact with another end portion of the light-emitting element 300 and the exposed upper surface of the second electrode 220. Another end portion of the light-emitting element 300 may be electrically connected to the second electrode 220 through the second contact electrode 262. The light-emitting element 300 has a semiconductor layer exposed on both end surfaces thereof in an extending direction, and the first contact electrode 261 and the second contact electrode 262 may be in contact with the light-emitting element 300 on the end surfaces on which of the semiconductor layer is exposed. However, the disclosure is not limited thereto. In some cases, both end side surfaces of the light-emitting element 300 may be partially exposed. During the manufacturing process of the display device 10, an insulating film 380 (see FIG. 4) surrounding an outer surface of the semiconductor layer of the light-emitting element 300 may be partially removed in a process of forming the second insulating layer 520 covering the outer surface of the light-emitting element 300, and the exposed side surface of the light-emitting element 300 may be in contact with the first contact electrode 261 and the second contact electrode 262.

In the drawing, it is illustrated that one first contact electrode 261 and one second contact electrode 262 are disposed in one sub-pixel PXn, but the disclosure is not limited thereto. The number of the first contact electrodes 261 and second contact electrodes 262 may vary depending on the number of the first electrodes 210 and second electrodes 220 disposed in each sub-pixel PXn.

The fourth insulating layer 530 may be disposed on the second contact electrode 262. Since the fourth insulating layer 530 may be disposed to cover the second contact electrode 262, the fourth insulating layer 530 may electrically insulate the first contact electrode 261 and the second contact electrode 262 from each other. Specifically, the fourth insulating layer 530 may be disposed to cover the second contact electrode 262 and may not be disposed on another end portion of the light-emitting element 300 so that the light-emitting element 300 may be in contact with the first contact electrode 261. The fourth insulating layer 530 may be partially in contact with the second contact electrode 262 and the third insulating layer 520 at an upper surface of the third insulating layer 520. A side surface of the fourth insulating layer 530 in a direction in which the first electrode 210 may be disposed may be aligned with a side surface of the third insulating layer 520. However, the disclosure is not limited thereto.

The first contact electrode 261 may be disposed on the first electrode 210, the third insulating layer 520, and the fourth insulating layer 530. The first contact electrode 261 may be in contact with an end portion of the light-emitting element 300 and the exposed upper surface of the first electrode 210. An end portion of the light-emitting element 300 may be electrically connected to the second electrode 210 through the first contact electrode 261.

For example, the second contact electrode 262 may be disposed between the first electrode 220 and the fourth insulating layer 530, and the first contact electrode 261 may be disposed on the fourth insulating layer 530. The first contact electrode 261 may be partially in contact with the third insulating layer 520, the fourth insulating layer 530, the first electrode 210, and the light-emitting element 300. An end portion of the first contact electrode 261 in a direction in which the second electrode 220 may be disposed may be disposed on the fourth insulating layer 530. The first contact electrode 261 and the second contact electrode 262 may not be in contact with each other due to the third insulating layer 520 and the fourth insulating layer 530. However, the disclosure is not limited thereto, and in some cases, the fourth insulating layer 530 may be omitted.

The contact electrodes 261 and 262 may include a conductive material. For example, the contact electrodes 261 and 262 may include ITO, IZO, ITZO, aluminum (Al), or the like, or a combination thereof. However, the disclosure is not limited thereto.

The fifth insulating layer 550 may be entirely disposed on the first substrate 110. The fifth insulating layer 550 may serve to protect members disposed on the first substrate 110 from an external environment.

Each of the second insulating layer 510, the third insulating layer 520, the fourth insulating layer 530, and the fifth insulating layer 550, which are described above, may include an inorganic insulating material or an organic insulating material. In one or more embodiments, the second insulating layer 510, the third insulating layer 520, the fourth insulating layer 530, and the fifth insulating layer 550 may each include an inorganic insulating material such as silicon oxide (SiOx), silicon nitride (SiNx), silicon oxynitride (SiOxNy), aluminum oxide (Al2O3), aluminum nitride (AlN), or the like, or a combination thereof. Further, the second insulating layer 510, the third insulating layer 520, the fourth insulating layer 530, and the fifth insulating layer 550 may each include acrylic resin, epoxy resin, phenol resin, polyamide resin, polyimide resin, unsaturated polyester resin, polyphenylene resin, polyphenylene sulfide resin, benzocyclobutene, cardo resin, siloxane resin, silsesquioxane resin, polymethylmethacrylate, polycarbonate, polymethylmethacrylate-polycarbonate synthetic resin, or the like as an organic insulating material. However, the disclosure is not limited thereto.

The light-emitting element 300 may be a light-emitting diode, and specifically, may be an inorganic light-emitting diode having a size of a micrometer unit or a nanometer unit and made of an inorganic material. The inorganic light-emitting diode may be aligned between two electrodes in which polarity may be formed by forming an electric field in a specific direction between the two electrodes facing each other. The light-emitting element 300 may be aligned between two electrodes due to the electric field formed on the two electrodes.

The light-emitting element 300 according to one or more embodiments may have a shape extending in a direction. The light-emitting element 300 may have a shape of a rod, a wire, a tube, or the like. In one or more embodiments, the light-emitting element 300 may have a cylindrical shape or a rod shape. However, the shape of the light-emitting element 300 is not limited thereto, and the light-emitting element 300 may have a shape of a cube, a rectangular parallelepiped, a polygonal pillar such as a hexagonal pillar, or the like or have a shape which extends in a direction and has a partially inclined outer surface. Thus, the light-emitting element 300 may have various shapes. Semiconductors included in the light-emitting element 300, which will be described below, may have a structure in which the semiconductors are sequentially disposed or stacked on each other in the direction.

The light-emitting element 300 may include a semiconductor layer doped with an arbitrary conductive-type (for example, p-type or n-type) impurity. The semiconductor layer may receive an electrical signal applied from an external power source and emit light in a specific wavelength range.

FIG. 4 is a schematic view of the light-emitting element according to one or more embodiments.

Referring to FIG. 4, the light-emitting element 300 may include a first semiconductor layer 310, a second semiconductor layer 320, an active layer 330, an electrode layer 370, and an insulating film 380.

The first semiconductor layer 310 may be an n-type semiconductor layer. As an example, in case that the light-emitting element 300 emits light in a blue wavelength range, the first semiconductor layer 310 may include a semiconductor material having a chemical formula of AlxGayIn1-x-yN (0<=x<=1, 0<=y<=1, and 0<=x+y<=1). For example, the semiconductor material may be at least one of AlGaInN, GaN, AlGaN, InGaN, AlN, or InN that are doped with an n-type impurity. The first semiconductor layer 310 may be doped with an n-type dopant. As an example, the n-type dopant may be Si, Ge, Sn, or the like, or a combination thereof. In one or more embodiments, the first semiconductor layer 310 may be n-GaN doped with n-type Si. A length of the first semiconductor layer 310 may range from about 1.5 μm to about 5 μm, but the disclosure is not limited thereto.

The second semiconductor layer 320 is disposed on the active layer 330 that will be described below. The second semiconductor layer 320 may be a p-type semiconductor. As an example, in case that the light-emitting element 300 emits light in a blue or green wavelength range, the second semiconductor layer 320 may include a semiconductor material having a chemical formula of AlxGayIn1-x-yN (0<=x<=1, 0<=y<=1, and 0<=x+y<=1). For example, the semiconductor material may be at least one of AlGaInN, GaN, AlGaN, InGaN, AlN, or InN that are doped with a p-type impurity. The second semiconductor layer 320 may be doped with a p-type dopant. As an example, the p-type dopant may be Mg, Zn, Ca, Se, Ba, or the like, or a combination thereof. In one or more embodiments, the second semiconductor layer 320 may be p-GaN doped with p-type Mg. A length of the second semiconductor layer 320 may range from 0.05 μm to 0.10 μm, but the disclosure is not limited thereto.

Each of the first semiconductor layer 310 and the second semiconductor layer 320 is illustrated in the drawing as being formed as one layer, but the disclosure is not limited thereto. According to some embodiments, each of the first semiconductor layer 310 and the second semiconductor layer 320 may further include a larger number of layers, e.g., a clad layer or a tensile strain barrier reducing (TSBR) layer according to a material of the active layer 330. A description thereof will be provided below with reference to other drawings.

The active layer 330 may be disposed between the first semiconductor layer 310 and the second semiconductor layer 320. The active layer 330 may include a material having a single or multiple quantum well structure. In case that the active layer 330 includes a material having a multiple quantum well structure, the active layer 330 may have a structure in which quantum layers and well layers are alternately stacked on each other. The active layer 330 may emit light due to a combination of electron-hole pairs in response to electrical signals applied through the first semiconductor layer 310 and the second semiconductor layer 320. As an example, in case that the active layer 330 emits light in a blue wavelength range, the active layer 330 may include a material such as AlGaN, AlGaInN, or the like, or a combination thereof. In particular, in case that the active layer 330 has a multiple quantum well structure in which quantum layers and well layers are alternately stacked on each other, the quantum layer may include a material such as AlGaN or AlGaInN, and the well layer may include a material such as GaN or AlInN. In one or more embodiments, the active layer 330 may include AlGaInN as a quantum layer and AlInN as a well layer. As described above, the active layer 330 may emit blue light having a central wavelength band ranging from 450 nm to 495 nm.

However, the disclosure is not limited thereto, and the active layer 330 may have a structure in which semiconductor materials having large bandgap energy and semiconductor materials having small bandgap energy are alternately stacked on each other or include other group Ill or group V semiconductor materials according to the wavelength range of emitted light. The light emitted by the active layer 330 is not limited to light in a blue wavelength range, and the active layer 330 may also emit light in a red or green wavelength range in some cases. A length of the active layer 330 may range from 0.05 μm to 0.10 μm, but the disclosure is not limited thereto.

The light emitted from the active layer 330 may be emitted to not only an outer surface of the light-emitting element 300 in a length direction but also the side surfaces of the light-emitting element 300. Directivity of the light emitted from the active layer 330 is not limited to a direction.

The electrode layer 370 may be an ohmic contact electrode. However, the disclosure is not limited thereto, and the electrode layer 370 may also be a Schottky contact electrode. The light-emitting element 300 may include at least one electrode layer 370. Although the light-emitting element 300 is illustrated in FIG. 4 as including a single electrode layer 370, the disclosure is not limited thereto. In some cases, the light-emitting element 300 may include a larger number of electrode layers 370, or the electrode layer 370 may be omitted. The description of the light-emitting element 300, which will be provided below, may be identically applied even in case that the number of the electrode layers 370 is varied or another structure is further included.

In case that the light-emitting element 300 is electrically connected to the electrodes 210 and 220 or the contact electrodes 261 and 262, the electrode layer 370 may reduce resistance between the light-emitting element 300 and the electrode or contact electrode. The electrode layer 370 may include a conductive metal. For example, the electrode layer 370 may include at least one of aluminum (Al), titanium (Ti), indium (In), gold (Au), silver (Ag), indium tin oxide (ITO), indium zinc oxide (IZO), or indium tin-zinc oxide (ITZO). Further, the electrode layer 370 may include a semiconductor material doped with an n-type or p-type impurity. The electrode layer 370 may include the same material or different materials, but the disclosure is not limited thereto.

The insulating film 380 is disposed to surround outer surfaces of the semiconductor layers and the electrode layers, which are described above. In one or more embodiments, the insulating film 380 may be disposed to surround at least an outer surface of the active layer 330 and may extend in a direction in which the light-emitting element 300 extends. The insulating film 380 may serve to protect the members. As an example, the insulating film 380 may be formed to surround side surface portions of the members and expose both end portions of the light-emitting element 300 in the length direction.

In the drawing, the insulating film 380 is illustrated as being formed to extend in the length direction of the light-emitting element 300 to cover from the first semiconductor layer 310 to a side surface of the electrode layer 370, but the disclosure is not limited thereto. Since the insulating film 380 covers only outer surfaces of some semiconductor layers, including the active layer 330 or covers only a portion of the outer surface of the electrode layer 370, the outer surface of the electrode layer 370 may be partially exposed. An upper surface of the insulating film 380 may be formed to be rounded in cross section in an area adjacent to at least one end portion of the light-emitting element 300.

A thickness of the insulating film 380 may range from 10 nm to 1.0 μm, but the disclosure is not limited thereto. In one or more embodiments, the thickness of the insulating film 380 may be about 40 nm.

The insulating film 380 may include a material having insulating properties, for example, silicon oxide (SiOx), silicon nitride (SiNx), silicon oxynitride (SiOxNy), aluminum nitride (AlN), aluminum oxide (Al2O3), or the like, or a combination thereof. Accordingly, it is possible to prevent an electrical short circuit that may occur in case that the active layer 330 is in direct contact with the electrode through which an electrical signal may be transmitted to the light-emitting element 300. Further, since the insulating film 380 protects the outer surface of the light-emitting element 300, including the active layer 330, it is possible to prevent degradation in light-emitting efficiency.

Further, in some embodiments, an outer surface of the insulating film 380 may be surface treated. In case that the display device 10 is manufactured, the light-emitting element 300 may be aligned by being sprayed on the electrodes in a state of being dispersed in an ink. Here, in order to maintain a state in which the light-emitting element 300 may be dispersed in the ink without aggregating with another adjacent light-emitting element 300, the surface of the insulating film 380 may be treated to be hydrophobic or hydrophilic.

The light-emitting element 300 may have a length h ranging from 1 μm to 10 μm or from 2 μm to 6 μm, and in one or more embodiments from 3 μm to 5 μm. A diameter of the light-emitting element 300 may range from 300 nm to 700 nm, and an aspect ratio of the light-emitting element 300 may range from 1.2 to 100. However, the disclosure is not limited thereto, and the light-emitting elements 300 included in the display device 10 may have different diameters according to a composition difference of the active layer 330. In one or more embodiments, the diameter of the light-emitting element 300 may have a range of about 500 nm.

In the display device 10 according to one or more embodiments, since the first electrode 210 may be disposed to cover only a side of the first inner bank 410, for example, a side opposite to another side of the first inner bank 410 facing the second inner bank 420, a distance between the first electrode 210 and the second electrode 220 may be greater than a distance between the first inner bank 410 and the second electrode 220. The light-emitting element 300 disposed between the first inner bank 410 and the second inner bank 420 may not overlap the first electrode 210 in the thickness direction.

As described above, in the display device 10, since the first electrode 210 may be disposed to cover only a side of the first inner bank 410, the vertical distance between the second electrode 220 and the first electrode 210 may be greater than the vertical distance between the second electrode 220 and the first voltage line 191. Accordingly, the electric field formed between the second electrode 220 and the first voltage line 191 has a higher intensity than the electric field formed between the second electrode 220 and the first electrode 210, and the light-emitting element 300 may be disposed with a high degree of alignment due to the electric field of a high intensity.

Hereinafter, the manufacturing process of the display device 10 will be described with reference to other drawings. Hereinafter, an order of the manufacturing process of the display device 10 will be described in detail, and a description of the method of forming each member will be omitted.

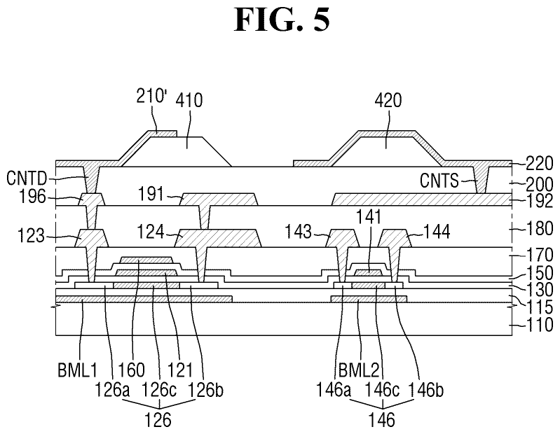

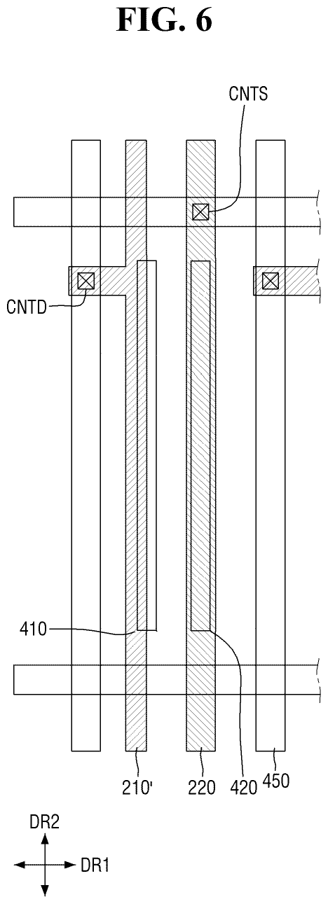

FIG. 5 is a schematic cross-sectional view illustrating a portion of a manufacturing process of the display device according to one or more embodiments. FIG. 6 is a schematic plan view illustrating a portion of a manufacturing process of the display device according to one or more embodiments.

First, referring to FIGS. 5 and 6, a first substrate 110, a circuit element layer disposed on the first substrate 110, and a first insulating layer 200 disposed on the circuit element layer are formed, and inner banks 410 and 420, a first electrode line 210′, and a second electrode 220 may be formed on the first insulating layer 200. As described above, the circuit element layer may include a first transistor 120, a second transistor 140, voltage lines 191 and 192, and the like. Detailed descriptions thereof will be omitted.

Specifically, a first inner bank 410 and a second inner bank 420 may be formed on the first insulating layer 200, and the first electrode line 210′ and the second electrode 220 may be respectively formed on the first inner bank 410 and the second inner bank 420. As described above, a width of the second electrode 220 measured in a direction is formed to be greater than a width of the second inner bank 420 measured in a direction so that the second electrode 220 may be disposed to cover an outer surface of the second inner bank 420. On the other hand, a width of the first electrode line 210′ measured in a direction is formed to be less than that of the second electrode 220 so that the first electrode line 210′ may be disposed to cover only a side surface of the first inner bank 410.

As shown in FIG. 6, during the manufacturing process of the display device 10, the first electrode line 210′ may be formed to extend in the second direction DR2 and disposed also in adjacent sub-pixel PXn. The first electrode line 210′ and the second electrode 220 may also be disposed in a non-display area NDA located at a peripheral portion of a display area DPA, and in a process of disposing light-emitting elements 300, the first electrode line 210′ and the second electrode 220 disposed in the non-display area NDA may be electrically connected to an external device (not shown) to directly receive an alignment signal. Thereafter, in a subsequent process, a process of disconnecting a partial area of the first electrode line 210′ may be performed, thereby forming a first electrode 210.

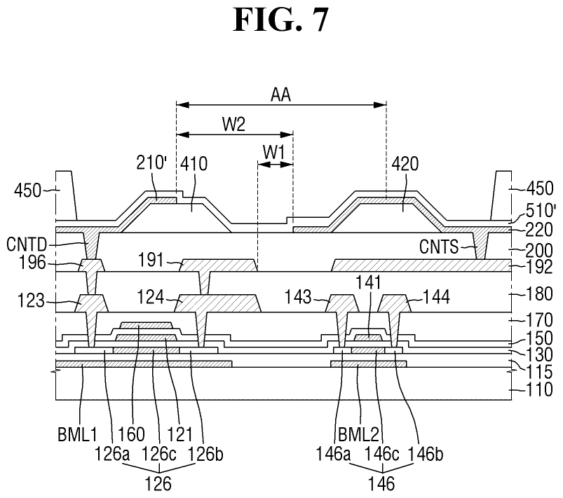

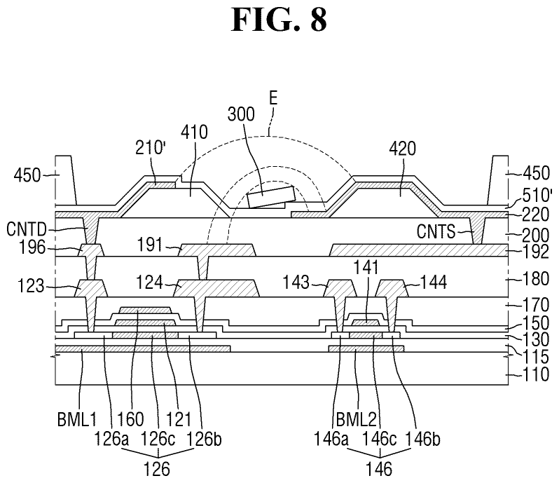

FIGS. 7 and 8 are cross-sectional views illustrating a portion of a manufacturing process of the display device according to one or more embodiments.

Subsequently, referring to FIG. 7, a second insulating material layer 510′ disposed to cover the first electrode line 210′ and the second electrode 220 may be formed on the first insulating layer 200, and an outer bank 450 may be formed on the second insulating material layer 510′. Since an opening (not shown) may not be formed in the second insulating material layer 510′ of FIG. 7, the second insulating material layer 510′ may entirely cover the first electrode line 210′ and the second electrode 220. In subsequent processes, the first insulating material layer 510′ may be partially etched, and an opening (not shown) partially exposing an upper surface of each of the first electrode 210 and the second electrode 220 may be formed, thereby forming a second insulating layer 510.

The outer bank 450 may be disposed at a boundary of each sub-pixel PXn on the second insulating material layer 510′ to surround the inner banks 410 and 420. The outer bank 450 may prevent ink sprayed on the electrodes 210 and 220 from overflowing to another adjacent sub-pixel PXn in the process of disposing the light-emitting elements 300. A description thereof may be the same as described above.

Referring to FIG. 8, an electric field E may be formed between the first electrode line 210′ and the second electrode 220 to align the light-emitting element 300 between the first electrode line 210′ and the second electrode 220. In some embodiments, the light-emitting element 300 may be sprayed in each pixel PX or sub-pixel PXn in a state of being dispersed in an ink through an inkjet process, and may be aligned between the electrodes 210 and 220 through the process of forming the electric field E between the first electrode line 210′ and the second electrode 220. In case that the light-emitting element 300 dispersed in the ink is sprayed and then an alignment signal is applied to the first electrode line 210′ and the second electrode 220, or a first voltage line 191 and a second voltage line 192, the electric field E is formed therebetween, and the light-emitting element 300 may receive a dielectrophoretic force due to the electric field. The light-emitting element 300 that has received the dielectrophoretic force may be aligned between the first electrode line 210′ and the second electrode 220 while an orientation direction and a position of the light-emitting element 300 may be changed in the ink.

Here, an electrode of the first electrode line 210′ and the second electrode 220 may be grounded, and alternating current (AC) power may be applied to another electrode. For example, in case that the first electrode line 210′ is grounded and the AC power is applied to the second electrode 220, the AC power may be directly applied to the second electrode 220 instead of a second voltage line. As described above, the process of applying AC power to the second electrode 220 may be performed through a line connected to the second electrode 220 during the manufacturing process of the display device 10, and thereafter, a process of disconnecting the line may be performed.

An alignment area AA, in which the light-emitting elements 300 may be disposed, may be formed between the first inner bank 410 and the second inner bank 420, or between the first electrode 210 and the second electrode 220. In the alignment area AA, an electric field may be formed due to an alignment signal applied to the first electrode 210 and the second electrode 220, or the first voltage line 191 and the second voltage line 192, and the light-emitting element 300 may be disposed between the first electrode 210 and the second electrode 220 by receiving a dielectrophoretic force due to the electric field.

As described above, in the display device 10 according to one or more embodiments, a vertical distance W2 (see FIG. 7) between the first electrode 210 or the first electrode line 210′ and the second electrode 220 may be greater than a vertical distance W1 (see FIG. 7) between the second electrode 220 and the first voltage line 191. In the process of disposing the light-emitting element 300, the alignment signal may be applied to each of the first electrode 210, the second electrode 220, the first voltage line 191, and the second voltage line 192. Unlike the first electrode 210, since the first voltage line 191 is disposed in a different layer from the second electrode 220, the vertical distance W1 between the first voltage line 191 and the second electrode 220 may be formed to be less than the vertical distance W2 between the first electrode 210 and the second electrode 220. Accordingly, an electric field of a higher intensity may be formed between the first voltage line 191 and the second electrode 220 than that of an electric field formed between the first electrode 210 and the second electrode 220. The light-emitting element 300 may receive a strong dielectrophoretic force due to the electric field of a high intensity, and may be disposed between the electrodes 210 and 220 with a high degree of alignment.

Further, since the first electrode 210 may be disposed on only a side of the first inner bank 410 and is not disposed on another side of the first inner bank 410, which may be spaced apart from and face the second inner bank 420, the electric field formed between the first voltage line 191 and the second electrode 220 may not be blocked by the first electrode 210. For example, according to one or more embodiments, the first electrode 210 may be disposed to cover a side of the first inner bank 410, and the first voltage line 191 may overlap another side of the first inner bank 410 in a thickness direction, in which the first electrode 210 may not be disposed. The first voltage line 191 may not overlap the first electrode 210 in the thickness direction at another side of the first inner bank 410.

The alignment signal may also be applied to the second voltage line 192 in the process of disposing the light-emitting element 300, and although not shown in the drawing, a vertical distance between the first voltage line 191 and the second voltage line 192 may be greater than the vertical distance W1 between the first voltage line 191 and the second electrode 220. Accordingly, in case that the alignment signal may be applied to each of the electrodes 210 and 220 and each of the voltage lines 191 and 192, the strongest electric field may be formed between the first voltage line 191 and the second electrode 220. However, the disclosure is not limited thereto.

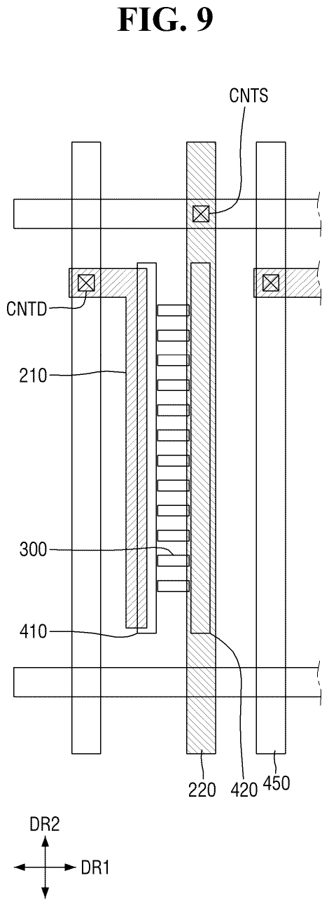

FIG. 9 is a schematic plan view illustrating a portion of a manufacturing process of the display device according to one or more embodiments.

Next, referring to FIG. 9, a portion of the first electrode line 210′ may be disconnected to form the first electrode 210. The process of disconnecting the first electrode line 210′ may be performed by a typical patterning process. Although not shown in the drawing, in the case of the second electrode 220, a process of disconnecting the line, which may be connected in the non-display area NDA and to which the alignment signal may be applied, may also be performed.

Next, a third insulating layer 520, a fourth insulating layer 530, a first contact electrode 261, and a second contact electrode 262 disposed on the light-emitting element 300 may be formed.

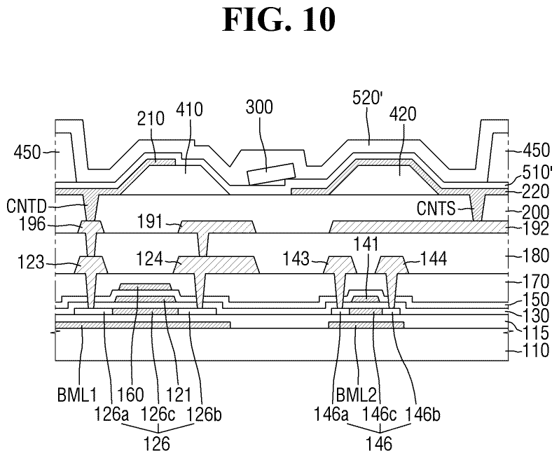

FIGS. 10 to 15 are schematic cross-sectional views illustrating a portion of a manufacturing process of the display device according to one or more embodiments.

First, referring to FIG. 10, a third insulating material layer 520′ disposed to cover the second insulating material layer 510′ may be formed on the second insulating material layer 510′. A partial area of the third insulating material layer 520′ may be patterned together with the second insulating material layer 510′ in a subsequent process to form the third insulating layer 520. The third insulating material layer 520′ may be entirely disposed on the second insulating material layer 510′, and may fix the light-emitting element 300 so that the light-emitting element 300 may not move in a subsequent process.

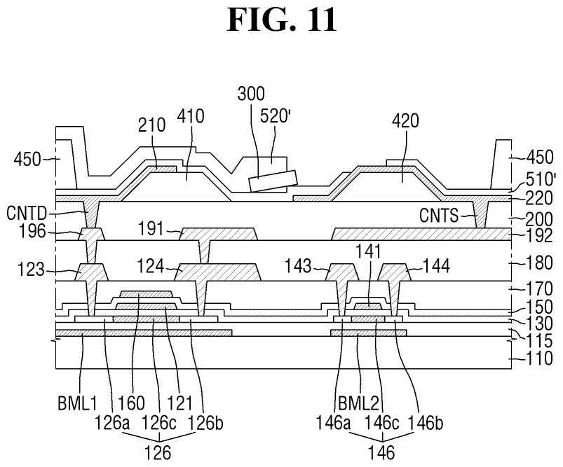

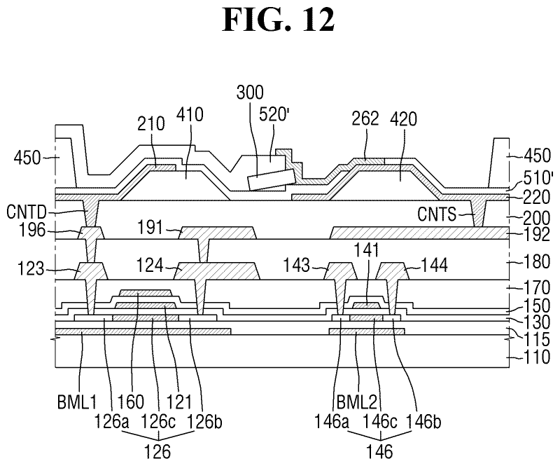

Next, referring to FIGS. 11 and 12, the second insulating material layer 510′ and the third insulating material layer 520′ may be partially patterned to expose a portion of the second electrode 220 and an end portion of the light-emitting element 300, and the second contact electrode 262 in contact with the exposed second electrode 220 and light-emitting element 300 may be formed. A portion of the second electrode 220, which may be disposed on the second inner bank 420, may be partially exposed. A process of patterning the second insulating material layer 510′ and the third insulating material layer 520′ and a process of forming the second contact electrode 262 may be performed by a typical patterning process. A detailed description thereof will be omitted.

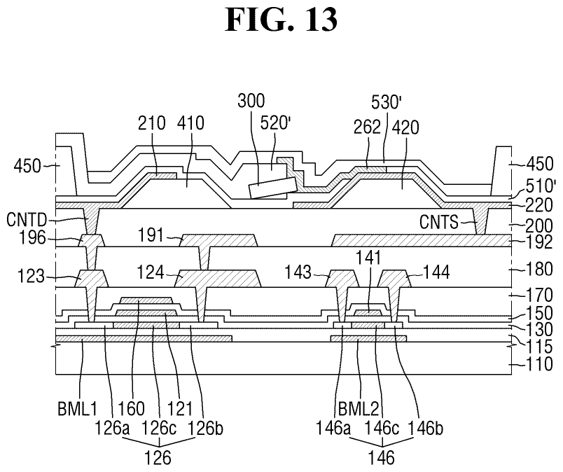

Next, referring to FIG. 13, a fourth insulating material layer 530′ disposed to cover the third insulating material layer 520′ and an upper surface of the second contact electrode 262 may be formed. The fourth insulating material layer 530′ may be partially patterned together with the third insulating material layer 520′ in a subsequent process to form the fourth insulating layer 530.

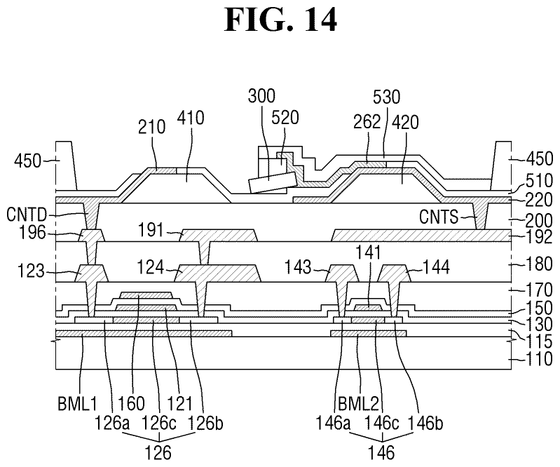

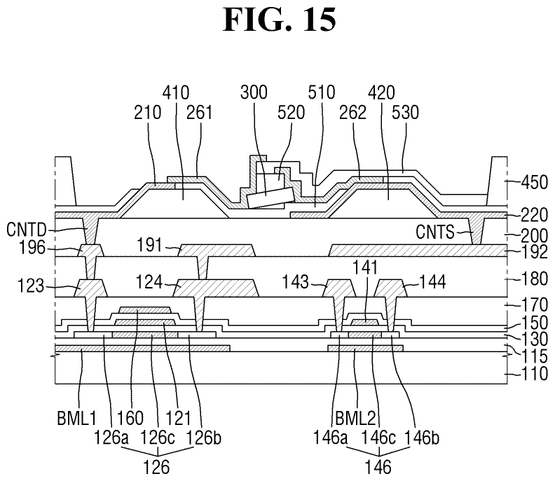

Next, referring to FIGS. 14 and 15, a partial area of each of the second insulating material layer 510′, the third insulating material layer 520′, and the fourth insulating material layer 530′ may be patterned to expose the first electrode 210 and another end portion of the light-emitting element 300, and the first contact electrode 261 in contact with the exposed first electrode 210 and light-emitting element 300 may be formed. A portion of the first electrode 210, which may be disposed on the first inner bank 410, may be partially exposed. The second insulating material layer 510′, the third insulating material layer 520′, and the fourth insulating material layer 530′ may be patterned in the process to respectively form the second insulating layer 510, the third insulating layer 520, and the fourth insulating layer 530.

In FIGS. 10 to 15, the first contact electrode 261 and the second contact electrode 262 are illustrated as being formed in different processes, including the process of forming the fourth insulating layer 530. However, the disclosure is not limited thereto, and the first contact electrode 261 and the second contact electrode 262 may be simultaneously formed in one process. This will be described in detail below with reference to other embodiments.

Subsequently, although not shown in the drawing, a fifth insulating layer 550 disposed to cover the members disposed on the first substrate 110 may be formed, thereby manufacturing the display device 10 according to one or more embodiments.

Hereinafter, various embodiments of the display device 10 will be described.

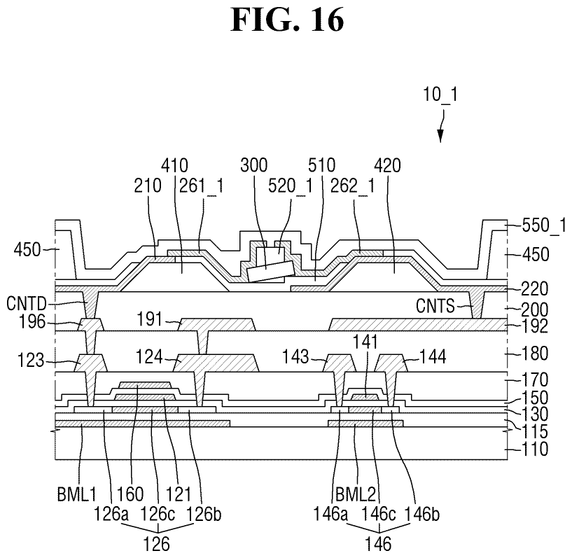

FIG. 16 is a schematic cross-sectional view illustrating a portion of a display device according to one or more other embodiments.

Referring to FIG. 16, in a display device 10_1 according to one or more embodiments, the fourth insulating layer 530 may be omitted. One or more embodiments may be different from one or more embodiments of FIG. 3 in that the fourth insulating layer 530 may be omitted. Hereinafter, repeated descriptions will be omitted, and descriptions will be provided based on differences from the above-described contents.

In the display device 10_1 of FIG. 16, the fourth insulating layer 530 may be omitted, and a first contact electrode 261_1 may be disposed directly on a third insulating layer 520_1. In some embodiments, in case that the third insulating layer 520_1 includes an organic insulating material, the first contact electrode 261_1 and a second contact electrode 262_1 may be simultaneously formed in one process.

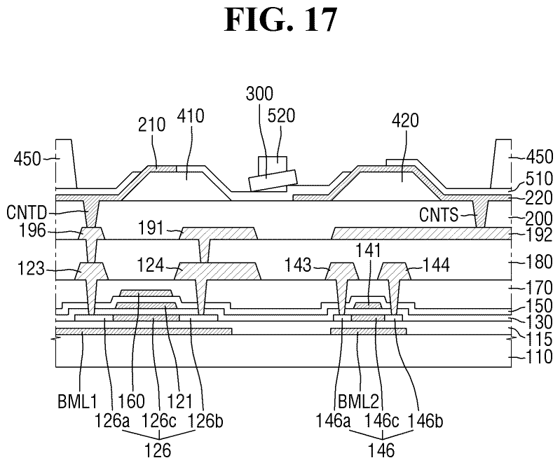

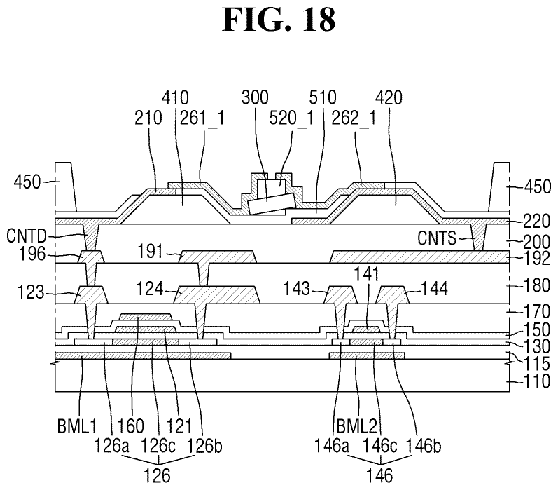

FIGS. 17 and 18 are schematic cross-sectional views illustrating a portion of a manufacturing process of the display device of FIG. 16.

Referring to FIGS. 17 and 18, after light-emitting elements 300 may be disposed between a first electrode 210 and a second electrode 220, a portion of an upper surface of each of the first electrode 210 and the second electrode 220 may be simultaneously exposed in a process of forming a third insulating layer 520_1 as shown in FIG. 17. Thereafter, the first contact electrode 261_1 and the second contact electrode 262_1 may be simultaneously formed but spaced apart from each other on the third insulating layer 520_1 disposed on the light-emitting element 300. Accordingly, a portion of a low surface of the first contact electrode 261_1 may be in direct contact with the third insulating layer 520_1. In the display device 10_1 according to one or more embodiments, since the third insulating layer 530 may be omitted, and the first contact electrode 261_1 and the second contact electrode 262_1 may be simultaneously formed in one process, the number of manufacturing processes of the display device 10_1 may be reduced.

The display device 10 may include a larger number of inner banks 410 and 420 and a larger number of electrodes 210 and 220.

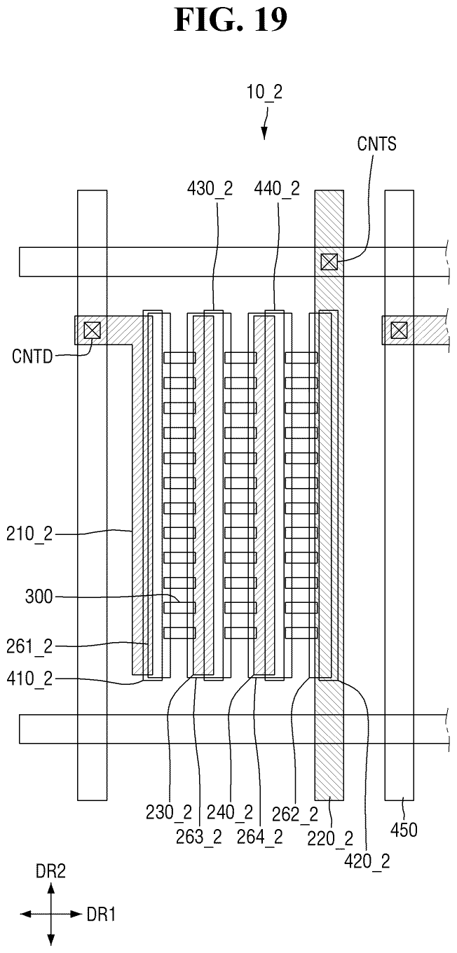

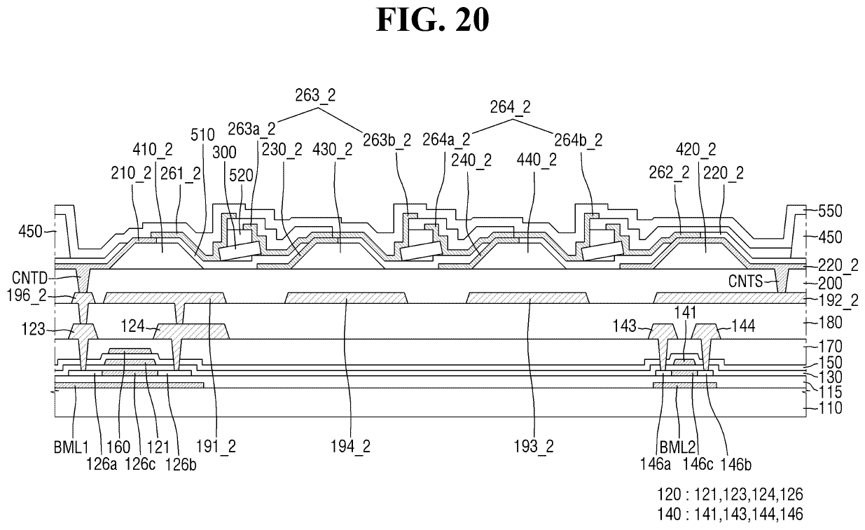

FIG. 19 is a schematic plan view illustrating a sub-pixel of a display device according to still one or more other embodiments. FIG. 20 is a schematic cross-sectional view illustrating a portion of the display device of FIG. 19.

Referring to FIGS. 19 and 20, a display device 10_2 according to one or more embodiments may further include a third inner bank 430_2 and a fourth inner bank 440_2 disposed between a first inner bank 410_2 and a second inner bank 420_2, a third electrode 230_2 and a fourth electrode 240_2 disposed between a first electrode 210_2 and a second electrode 220_2, and a third contact electrode 263_2 and a fourth contact electrode 264_2 disposed between a first contact electrode 261_2 and a second contact electrode 262_2. One or more embodiments may be different from one or more embodiments of FIGS. 2 and 3 in that the third inner bank 430_2, the fourth inner bank 440_2, the third electrode 230_2, and the fourth electrode 240_2 may be further included. Hereinafter, repeated descriptions will be omitted, and descriptions will be provided based on differences from the above-described contents.

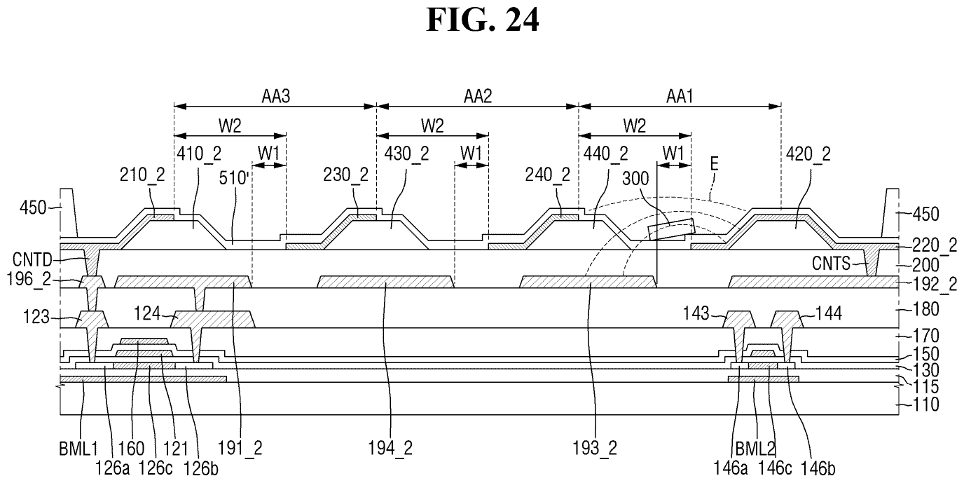

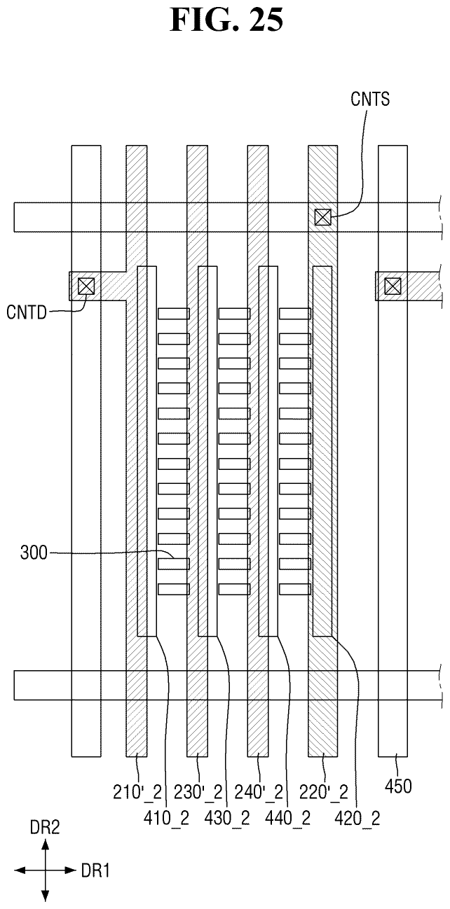

The display device 10_2 of FIGS. 24 and 25 may further include the third inner bank 430_2 and the fourth inner bank 440_2. The third inner bank 430_2 and the fourth inner bank 440_2 may have substantially the same structure as the first inner bank 410_2 and the second inner bank 420_2. For example, the third inner bank 430_2 and the fourth inner bank 440_2 may extend in the second direction DR2 in each sub-pixel PXn, and may face to be spaced apart respectively from the first inner bank 410_2 and the second inner bank 420_2 in the first direction DR1. For example, the first inner bank 410_2, the third inner bank 430_2, the fourth inner bank 440_2, and the second inner bank 420_2 may be sequentially disposed from a side of the sub-pixel PXn toward another side thereof in the first direction DR1 to be spaced apart from each other. As will be described below, alignment areas AA in which the light-emitting elements 300 may be disposed may be formed between the first inner bank 410_2, the third inner bank 430_2, the fourth inner bank 440_2, and the second inner bank 420_2, and a larger number of light-emitting elements 300 may be disposed for each sub-pixel PXn.

The third electrode 230_2 may be disposed on the third inner bank 430_2, and the fourth electrode 240_2 may be disposed on the fourth inner bank 440_2. The third electrode 230_2 and the fourth electrode 240_2 may each have a shape similar to that of the first electrode 210_2. The third electrode 230_2 and the fourth electrode 240_2 may be disposed to extend in the second direction DR2 on the third inner bank 430_2 and the fourth inner bank 440_2, respectively, and may be spaced apart from each other and face each other in the first direction DR1. For example, the first electrode 210_2, the third electrode 230_2, the fourth electrode 240_2, and the second electrode 220_2 may be sequentially disposed from a side of the sub-pixel PXn toward another side thereof in the first direction DR1 to be spaced apart from each other.

However, unlike the first electrode 210_2 and the second electrode 220_2, the third electrode 230_2 and the fourth electrode 240_2 may not be electrically connected to the circuit elements or lines disposed in each pixel PX or sub-pixel PXn. The first electrode 210_2 may be electrically connected to a first transistor 120 through a first conductive pattern 196, and the second electrode 220_2 may be electrically connected to a second voltage line 192_2, but the third electrode 230_2 and the fourth electrode 240_2 may be floating electrodes that are not electrically connected to the first transistor 120 and the second voltage line 192_2. The third electrode 230_2 and the fourth electrode 240_2 may be electrodes through which an electrical signal transmitted to the first electrode 210_2 and the second electrode 220_2 flows instead of directly transmitting an electrical signal applied from the circuit elements or lines.

According to one or more embodiments, the third electrode 230_2 may be disposed to cover only a side of the third inner bank 430_2, for example, a side facing the first inner bank 410_2, and the fourth electrode 240_2 may be disposed to cover only a side of the fourth inner bank 440_2, for example, a side facing the third inner bank 430_2. In the same manner as the first electrode 210_2, the third electrode 230_2 and the fourth electrode 240_2 may also be disposed to partially expose the third inner bank 430_2 and the fourth inner bank 440_2. As will be described below, in the display device 10_2, the second data conductive layer may include a larger number of conductive lines, and a vertical distance between each of the electrodes and each of the lines may be less than a vertical distance between the electrodes 210_2, 220_2, 230_2, and 240_2. Accordingly, the third electrode 230_2 and the fourth electrode 240_2 may be disposed to cover only portions of the third inner bank 430_2 and the fourth inner bank 440_2, respectively, so as not to block an electric field formed between each of the electrodes and each of the conductive lines. A detailed description thereof will be provided below with reference to other drawings.

The third contact electrode 263_2 may be further disposed on the third electrode 230_2, and the fourth contact electrode 264_2 may be further disposed on the fourth electrode 240_2. Unlike the first contact electrode 261_2 and the second contact electrode 262_2, the third contact electrode 263_2 and the fourth contact electrode 264_2 may have a greater width than the respective electrodes. According to one or more embodiments, a width of each of the third contact electrode 263_2 and the fourth contact electrode 264_2 measured in a direction may be greater than a width of each of the third electrode 230_2 and the fourth electrode 240_2 measured in the direction. Accordingly, the third contact electrode 263_2 may be simultaneously in contact with the light-emitting element 300 disposed between the first electrode 210_2 and the third electrode 230_2 and the light-emitting element 300 disposed between the third electrode 230_2 and the fourth electrode 240_2. The fourth contact electrode 264_2 may be simultaneously in contact with the light-emitting element 300 disposed between the third electrode 230_2 and the fourth electrode 240_2 and the light-emitting element 300 disposed between the fourth electrode 240_2 and the second electrode 220_2.

Specifically, according to one or more embodiments, in the display device 10_2, the third contact electrode 263_2 may include a third-first contact electrode 263a_2 and a third-second contact electrode 263b_2, and the fourth contact electrode 264_2 may include a fourth-first contact electrode 264a_2 and a fourth-second contact electrode 264b_2. As shown in FIG. 20, the third-first contact electrode 263a_2 may be in contact with an end portion of the light-emitting element 300, which may be disposed between the first electrode 210_2 and the third electrode 230_2, and the third electrode 230_2, and the third-second contact electrode 263b_2 may be in contact with an end portion of the light-emitting element 300, which may be disposed between the third electrode 230_2 and the fourth electrode 240_2, and the third electrode 230_2. The fourth-first contact electrode 264a_2 may be in contact with another end portion of the light-emitting element 300, which may be disposed between the third electrode 230_2 and the fourth electrode 240_2, and the fourth electrode 240_2, and the fourth-second contact electrode 264b_2 may be in contact with an end portion of the light-emitting element 300, which may be disposed between the fourth electrode 240_2 and the second electrode 220_2, and the fourth electrode 240_2.

During the manufacturing process of the display device 10_2, a process of forming the contact electrodes may be performed twice. Among these, the third-first contact electrode 263a_2 and the fourth-first contact electrode 264a_2 may be simultaneously formed in a process of forming the second contact electrode 262_2, and the third-second contact electrode 263b_2 and the fourth-second contact electrode 264b_2 may be simultaneously formed in a process of forming the first contact electrode 261_2. The third-first contact electrode 263a_2 and the third-second contact electrode 263b_2 may each be in contact with the third electrode 230_2, and simultaneously, may be in contact with each other, thereby forming a third contact electrode 263_2. In the same aspect, the fourth-first contact electrode 264a_2 and the fourth-second contact electrode 264b_2 may each be in contact with the fourth electrode 240_2, and simultaneously, in contact with each other, thereby forming a fourth contact electrode 264_2. As an example, the third-first contact electrode 263a_2 and the third-second contact electrode 263b_2 may be in contact with each other on the third electrode 230_2, and the fourth-first contact electrode 264a_2 and the fourth-second contact electrode 264b_2 may be in contact with each other on the fourth electrode 240_2, but in some cases, a contact electrode may be disposed on another contact electrode to contact each other.

However, the disclosure is not limited thereto. In some cases, the third-first contact electrode 263a_2 and the third-second contact electrode 263b_2, and the fourth-first contact electrode 264a_2 and the fourth-second contact electrode 264b_2 may be respectively in contact with the third electrode 230_2 and the fourth electrode 240_2, but may be spaced apart therefrom without being in contact therewith. Some of the light-emitting elements 300 may receive an electrical signal from the first electrode 210_2 and the second electrode 220_2 through the third contact electrode 263_2 and the fourth contact electrode 264_2 even though the third electrode 230_2 and the fourth electrode 240_2 may be floating electrodes.

In case that an electrical signal is transmitted through the first electrode 210_2, the electrical signal may be transmitted to an end portion of the light-emitting element 300 disposed between the first electrode 210_2 and the third electrode 230_2. The electrical signal may be transmitted to the third contact electrode 263_2 and the third electrode 230_2, and may be transmitted to the light-emitting element 300 disposed between the third electrode 230_2 and the fourth electrode 240_2. In the same manner, the electrical signal may be transmitted to the fourth contact electrode 264_2 and the fourth electrode 240_2, and may be transmitted to the light-emitting element 300 disposed between the fourth electrode 240_2 and the second electrode 220_2. The light-emitting element 300 disposed between the third electrode 230_2 and the fourth electrode 240_2 may receive the electrical signal transmitted through each of the first electrode 210_2 and the second electrode 220_2 only through the third electrode 230_2 and the fourth electrode 240_2, respectively, and these may be connected in series. The display device 10_2 according to one or more embodiments may further include the third electrode 230_2 and the fourth electrode 240_2 so that some of the light-emitting elements 300 may be connected in series, thereby improving light-emitting efficiency.

In the drawing, it is illustrated that one third inner bank 430_2, one third electrode 230_2, one fourth inner bank 440_2 and one fourth electrode 240_2 are disposed, but the disclosure is not limited thereto. In some cases, the number of the third electrode 230_2 and fourth electrode 240_2 disposed between the first electrode 210_2 and the second electrode 220_2 may be increased, and in some embodiments, among these, an electrode may be omitted. It is apparent that the above description is similarly applicable to the third inner bank 430_2 and the fourth inner bank 440_2.

Further, since the display device 10_2 includes a larger number of electrodes, a larger number of conductive lines may also be disposed on the second data conductive layer. The second data conductive layer may further include a third voltage line 193_2 and a fourth voltage line 194_2, and during the manufacturing process of the display device 10_2, the alignment signal applied through the third voltage line 193_2 and the fourth voltage line 194_2 may form an electric field in alignment areas AA.

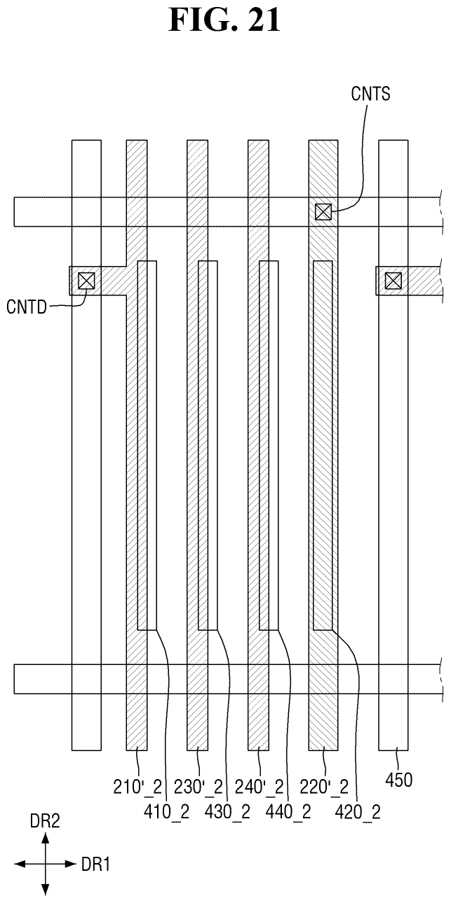

FIGS. 21 to 26 are schematic cross-sectional views and plan views illustrating a portion of the manufacturing process of the display device of FIG. 19.

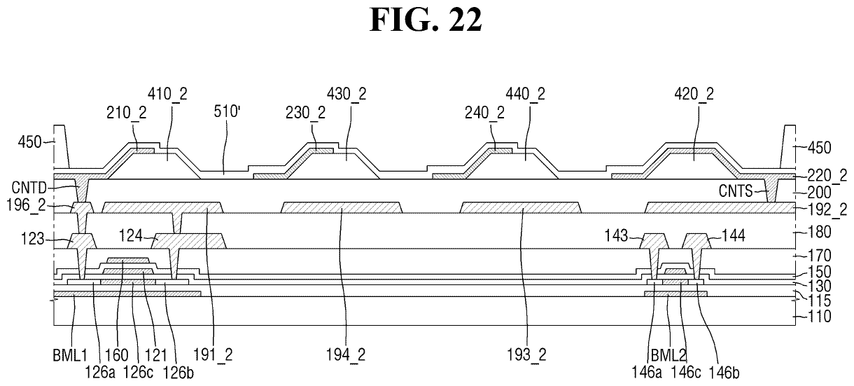

First, referring to FIGS. 21 and 22, a first inner bank 410_2, a second inner bank 420_2, a third inner bank 430_2, and a fourth inner bank 440_2 may be formed on a first insulating layer 200, and a first electrode line 210′_2, a second electrode 220_2, a third electrode line 230′_2, and a fourth electrode line 240′_2, which may be disposed respectively on the first inner bank 410_2, the second inner bank 420_2, the third inner bank 430_2, and the fourth inner bank 440_2, may be formed. A description for the arrangement thereof may be the same as described above. For example, the second electrode 220_2 may be formed to have a greater width than the second inner bank 420_2 and disposed to cover an outer surface of the second inner bank 420_2, and the first electrode line 210′ 2, the third electrode line 230′ 2, and the fourth electrode line 240′_2 may be disposed to cover only respective one sides of the first inner bank 410_2, the third inner bank 430_2, and the fourth inner bank 440_2. The first electrode line 210′_2, the third electrode line 230′_2, and the fourth electrode line 240′_2 may be partially disconnected in a subsequent process to form a first electrode 210_2, a third electrode 230_2, and a fourth electrode 240_2, respectively.

The second data conductive layer may further include a third voltage line 193_2 and a fourth voltage line 194_2 in addition to a first voltage line 191_2 and a second voltage line 192_2. The first power voltage may be applied to the third voltage line 193_2 in the same manner as the first voltage line 191_2, and the second power voltage may be applied to the fourth voltage line 194_2 in the same manner as the second voltage line 192_2. As described above, since a vertical distance between the electrodes disposed on the first insulating layer 200 may be formed to be greater than a vertical distance between each of the electrodes and each of the voltage lines, a stronger electric field may be formed between each of the electrodes and each of the voltage lines during the manufacturing process of the display device 10_2.

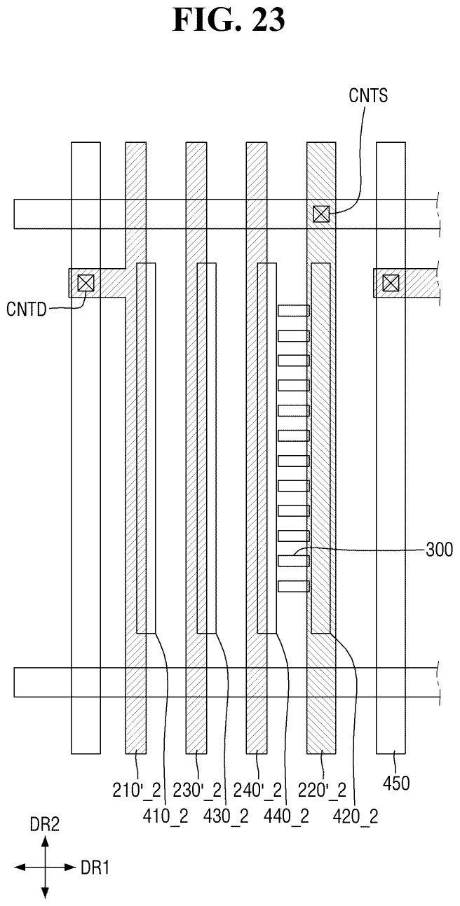

Referring to FIGS. 23 and 24, first, an electric field E may be formed between the second electrode 220_2 and the fourth electrode line 240′_2 to align the light-emitting element 300 between the fourth electrode line 240′ 2 and the second electrode 220_2.

A first alignment area AA1 may be formed between the second inner bank 420_2 and the fourth inner bank 440_2, a second alignment area AA2 may be formed between the fourth inner bank 440_2 and the third inner bank 430_2, and a third alignment area AA3 may be formed between the third inner bank 430_2 and the first inner bank 410_2. As described above, an electric field may be formed in each of the alignment areas AA1, AA2, and AA3 due to an alignment signal applied to each of the electrode 220_2 or the electrode lines 210′ 2, 230′_2, and 240′_2, and the voltage lines 191_2, 192_2, 193_2, and 194_2, and the light-emitting element 300 may be disposed between the first electrode 210 and the second electrode 220 by receiving a dielectrophoretic force due to the electric field.

As described above, in the display device 10_2 according to one or more embodiments, a vertical distance W2 (FIG. 24) between an electrode and another electrode adjacent thereto may be greater than a vertical distance W1 (FIG. 24) between the electrode and the voltage line adjacent thereto.

For example, the vertical distance W1 between the second electrode 220_2 and the third voltage line 193_2 disposed below the fourth inner bank 440_2 may be formed to be less than the vertical distance W2 between the second electrode 220_2 and the fourth electrode line 240′ 2 or the fourth electrode 240_2. Since the fourth electrode 240_2 or the fourth electrode line 240′_2 may be disposed only on a side of the fourth inner bank 440_2 and may not be disposed on another side thereof, which may be disposed to be spaced apart from and face the second inner bank 420_2, the electric field formed between the third voltage line 193_2 and the second electrode 220_2 may not be blocked by the fourth electrode 240_2 or the fourth electrode line 240′_2. For example, according to one or more embodiments, the fourth electrode 240_2 may be disposed to cover a side of the fourth inner bank 440_2, and the third voltage line 193_2 may overlap another side of the fourth inner bank 440_2, on which the fourth electrode 240_2 may not be disposed, in the thickness direction. The third voltage line 193_2 may not overlap the fourth electrode 240_2 in the thickness direction at another side of the fourth inner bank 440_2.

Accordingly, an electric field of a higher intensity may be formed between the third voltage line 193_2 and the second electrode 220_2 than between the second electrode 220_2 and the fourth electrode 240_2 or the fourth electrode line 240′_2. The light-emitting element 300 may receive a strong dielectrophoretic force due to the electric field of a high intensity, and may be disposed between the electrodes with a high degree of alignment. A vertical distance between the second voltage line 192_2 and the third voltage line 193_2 may be greater than the vertical distance W1 between the third voltage line 193_2 and the second electrode 220_2. A description thereof may be the same as described above.

In the same aspect, the vertical distance W1 between the fourth electrode 240_2 or the fourth electrode line 240′_2 and the fourth voltage line 194_2 disposed below the third inner bank 430_2 may be formed to be less than the vertical distance W2 between the fourth electrode 240_2 or the fourth electrode line 240′ 2 and the third electrode line 230′ 2 or the third electrode 230_2. Further, the vertical distance W1 between the third electrode 230_2 or the third electrode line 230′ 2 and the first voltage line 191_2 disposed below the first inner bank 410_2 may be formed to be less than the vertical distance W2 between the third electrode 230_2 or the third electrode line 230′ 2 and the first electrode line 210′ 2 or the first electrode 210_2. According to one or more embodiments, the third electrode 230_2 may be disposed to cover a side of the third inner bank 430_2, and the fourth voltage line 194_2 may overlap another side of the third inner bank 430_2, on which the third electrode 230_2 may not be disposed, in the thickness direction. The fourth voltage line 194_2 may not overlap the third electrode 230_2 in the thickness direction at another side of the third inner bank 430_2.

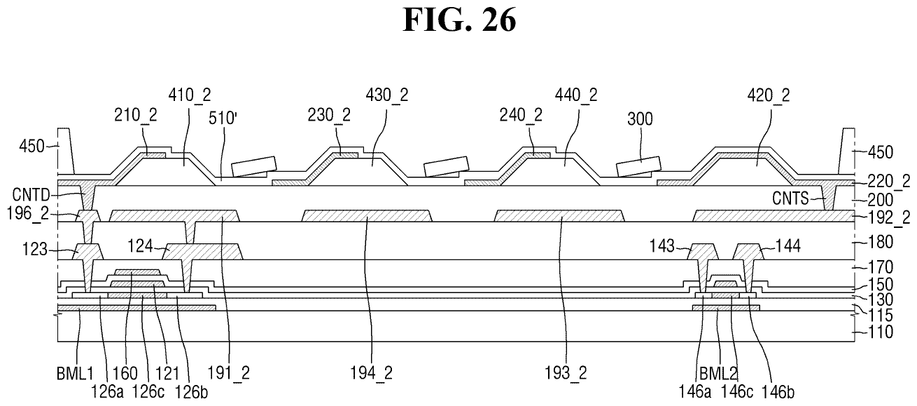

Referring to FIGS. 25 and 26, the light-emitting element 300 is also aligned in each of the second alignment area AA2 and the third alignment area AA3. In the drawing, the light-emitting elements 300 are illustrated as being aligned in each of the alignment areas AA1, AA2, and AA3 in different processes, but the disclosure is not limited thereto. In some cases, the light-emitting elements 300 disposed in the first alignment area AA1, the second alignment area AA2, and the third alignment area AA3 may be aligned simultaneously in the same process.

Thereafter, although not shown in the drawing, the display device 10_2 of FIG. 19 may be manufactured by forming the third insulating layer 520, the first contact electrode 261_2, the second contact electrode 262_2, the third contact electrode 263_2, the fourth contact electrode 264_2, the fourth insulating layer 530, and the fifth insulating layer 550 on the light-emitting element 300. A detailed description thereof will be omitted.

Further, the display device 10 may include a larger number of first electrodes 210 and second electrodes 220 so that a larger number of light-emitting elements 300 may be disposed for each sub-pixel PXn and may be connected in parallel.

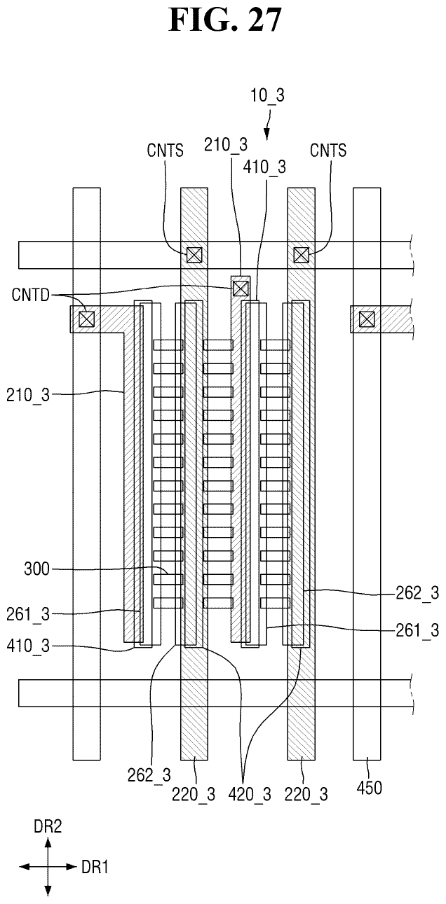

FIG. 27 is a schematic plan view illustrating a sub-pixel of a display device according to yet one or more other embodiments.

Referring to FIG. 27, a display device 10_3 according to one or more embodiments may include first inner banks 410_3, second inner banks 420_3, first electrodes 210_3, and second electrodes 220_3, and light-emitting elements 300 may be disposed therebetween. One or more embodiments may be different from one or more embodiments of FIG. 2 in that a larger number of inner banks 410_3 and 420_3 and electrodes 210_3 and 220_3 may be included. Hereinafter, repeated descriptions will be omitted, and descriptions will be provided based on differences from the above-described contents.

In the display device 10_3 of FIG. 27, the first inner banks 410_3 and the second inner bank 420_3 may be disposed, and may be alternately disposed in the first direction DR1 in a sub-pixel PXn. The first electrodes 210_3 and the second electrode 220_3 may be disposed, and may be alternately disposed in the first direction DR1. One or more embodiments may be understood as one or more embodiments in which a pair of inner banks 410_3 and 420_3 and a pair of electrodes 210_3 and 220_3 may be further disposed in a sub-pixel PXn in one or more embodiments of FIG. 2. In the same manner, a pair of first contact electrode 261_3 and second contact electrode 262_3 may also be further disposed. Although not shown in the drawing, the second data conductive layer may also include a larger number of first voltage lines 191 and second voltage lines 192. In one or more embodiments, each sub-pixel PXn may have a greater area and a larger number of electrodes may be disposed, so that the number of the light-emitting elements 300 disposed per unit sub-pixel PXn may be increased. Each of the light-emitting elements 300 may be connected in parallel with each other, and the amount of light emitted per unit sub-pixel PXn may be increased.

In some embodiments, each of the first electrode 210 and the second electrode 220 may further include a stem portion extending in the first direction DR1.

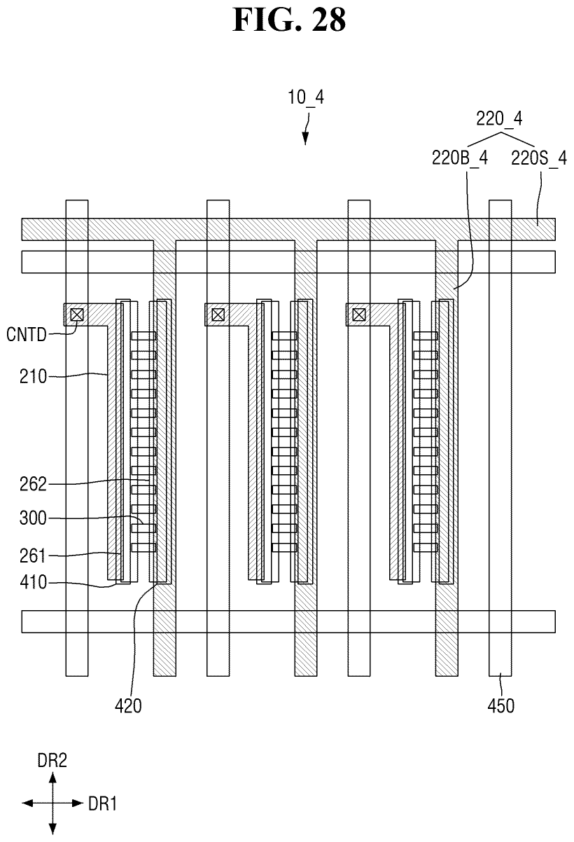

FIG. 28 is a schematic plan view illustrating a pixel of a display device according to yet one or more other embodiments.

Referring to FIG. 28, in a display device 10_4 according to one or more embodiments, a second electrode 220_4 may include a second electrode stem portion 220S_4 extending in the first direction DR1, and second electrode branch portions 220B_4 branched from the second electrode stem portion 220S_4 in the second direction DR2. One or more embodiments may be different from one or more embodiments of FIG. 2 in that a shape of the second electrode 220_4 may be different. Hereinafter, repeated descriptions will be omitted, and descriptions will be provided based on differences from the above-described contents.

In the display device 10_4 of FIG. 28, the second electrode 220_4 may include the second electrode stem portion 220S_4. The second electrode stem portion 220S_4 may be disposed to extend in the first direction DR1 to cross adjacent sub-pixels PXn, and the sub-pixels PXn or pixels PX adjacent in the first direction DR1 may share a second electrode stem portion 220S_4. The second electrode branch portions 220B_4 branched from the second electrode stem portion 220S_4 may be disposed in each of the sub-pixels PXn. The second electrode branch portion 220B_4 may be disposed on a second inner bank 420 and may be spaced apart from and face a first electrode 210. For example, the second electrode branch portion 220B_4 of FIG. 28 may be substantially the same as the second electrode 220 of FIG. 2.

The second electrode stem portion 220S_4 may extend in the first direction DR1 and may also be disposed in a non-display area NDA located at a peripheral portion of a display area DPA. Although not shown in the drawing, unlike one or more embodiments of FIG. 2, the second electrode contact hole CNTS (FIG. 2) may not be formed for each sub-pixel PXn, and the second electrode 220_4 may be electrically connected to a second voltage line 192 through a second electrode contact hole CNTS formed in the non-display area NDA. In the display device 10_4 according to one or more embodiments, the sub-pixels PXn sharing a second electrode stem portion 220S_4 may receive the same electrical signal, for example, the second power voltage VSS, through the second electrode 220_4. In this case, the second voltage line 192 may not be disposed for each sub-pixel PXn.

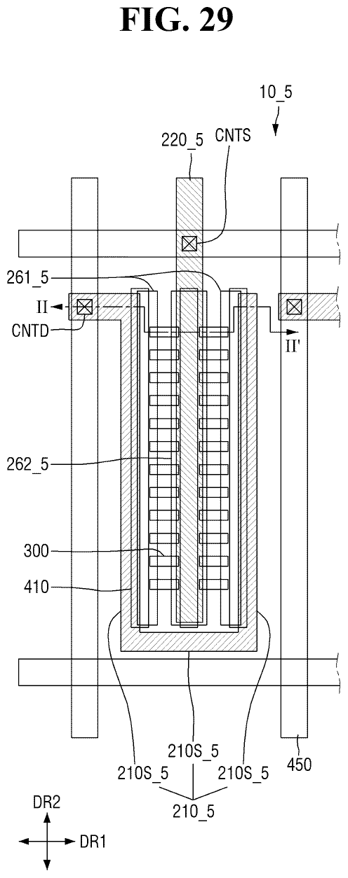

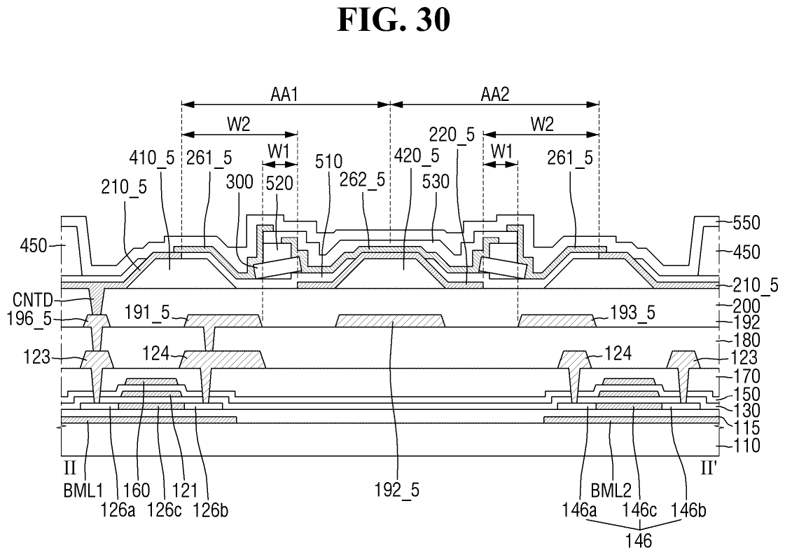

FIG. 29 is a schematic plan view illustrating a sub-pixel of a display device according to yet one or more other embodiments. FIG. 30 is a schematic cross-sectional view taken along line II-II′ of FIG. 29.

Referring to FIGS. 29 and 30, a display device 10_5 according to one or more embodiments may include first inner banks 410_5, and a second inner bank 420_5 may be disposed between the first inner banks 410_5. A first electrode 210_5 may include a first electrode stem portion 210S_5 and first electrode branch portions 210B_5, and a second electrode 220_5 may be disposed between the first electrode branch portions 210B_5. One or more embodiments may be different from one or more embodiments of FIGS. 2 and 3 in that the first inner banks 410_5 and the first electrode 210_5 may be further included. Hereinafter, repeated descriptions will be omitted, and descriptions will be provided based on differences from the above-described contents.

The display device 10_5 of FIGS. 26 and 27 may include the first inner banks 410_5, and the second inner bank 420_5 may be disposed between the first inner banks 410_5. For example, the first inner bank 410_5 and the second inner bank 420_5 may be alternately disposed in each sub-pixel PXn, and may be spaced apart from each other and face each other. An alignment area AA, which is an area in which light-emitting elements 300 may be disposed, may be formed between the first inner bank 410_5 and the second inner bank 420_5, and between the second inner bank 420_5 and the first inner bank 410_5, so that a larger number of light-emitting elements 300 may be disposed. For example, one or more embodiments may be understood as one or more embodiments in which the first inner bank 410_5, which may be spaced apart from a side of the second inner bank 420_5 in the first direction DR1, may be further disposed on a side of the second inner bank 420_5 in one or more embodiments of FIGS. 2 and 3.

The first electrode 210_5 may include the first electrode stem portion 210S_5 extending in the first direction DR1, and first electrode branch portions 210B_5 branched from the first electrode stem portion 210S_5 in the second direction DR2. The first electrode branch portions 210B_5 may each be disposed on the first inner bank 410_5, and may be connected to each other by the first electrode stem portion 210S_5. The first electrode 210_5 may be electrically connected to a first transistor 120 through a first electrode contact hole CNTD in an area overlapping an outer bank 450.

Both sides of the second electrode 220_5 may each be spaced apart from and face each of the first electrode branch portions 210B_5. For example, one or more embodiments may be understood as one or more embodiments in which the first electrode branch portion 210B_5, which may be spaced apart from a side of the second electrode 220_5 in the first direction DR1, may be further disposed on a side of the second electrode 220_5 in one or more embodiments of FIGS. 2 and 3, and the first electrode branch portions 210B_5 may be electrically connected to each other through the first electrode stem portion 210S_5.

First contact electrodes 261_5 may be respectively disposed on the first electrode branch portions 210B_5. Unlike FIG. 2, a larger number of first contact electrodes 261_5 may be disposed.

Light-emitting elements 300 are disposed in each of alignment areas AA1 and AA2 formed between the first inner bank 410_5 and the second inner bank 420_5, and at least one end portion of each of the light-emitting elements 300 may be electrically connected to the first electrode branch portion 210B_5 through the first contact electrodes 261_5. In one or more embodiments, the light-emitting elements 300 disposed in different areas may each be electrically connected to the first electrode branch portion 210B_5 on at least one end portion thereof, and thus may simultaneously receive an electrical signal from the first electrode 210_5. The other end portion of each of the light-emitting elements 300 disposed in the different alignment areas AA1 and AA2 may be in contact with a second contact electrode 262_5. According to one or more embodiments, a width of the second contact electrode 262_5 measured in a direction may be formed to be greater than a width of the second electrode 220_5 measured in the direction, and the second contact electrode 262_5 may be disposed to cover the second electrode 220_5. The light-emitting elements 300 disposed in the different alignment areas AA1 and AA2 may be electrically connected to the second electrode 220_5 through the second contact electrode 262_5 and may simultaneously receive an electrical signal from the second voltage line 192. For example, the light-emitting elements 300 of one or more embodiments may be connected in parallel. A description of other members, except for the above description, is the same as described above, and thus a detailed description thereof will be omitted.

In concluding the detailed description, those skilled in the art will appreciate that many variations and modifications can be made to the embodiments without substantially departing from the principles of the disclosure. Therefore, the disclosed embodiments of the disclosure are used in a generic and descriptive sense only and not for purposes of limitation.

What is claimed is:

1. A display device comprising:
a first inner bank and a second inner bank that are disposed on a substrate and spaced apart from each other in a first direction that is parallel to the substrate, each of the first inner bank and the second inner bank extending in a second direction that is parallel to the substrate and perpendicular to the first direction;
a first electrode disposed on a partial area of the first inner bank and not on the second inner bank;
a second electrode covering the second inner bank and not the first inner bank, spaced apart from the first electrode in the first direction, and located closer to the first inner bank than to the first electrode in plan view; and
a light-emitting element between the first electrode and the second electrode,
wherein a first end portion of the light-emitting element does not overlap the first electrode or the second electrode in a third direction perpendicular to both the first direction and the second direction, and
wherein a second end portion of the light-emitting element overlaps the second electrode and does not overlap the first electrode in the third direction.

2. The display device of claim 1, further comprising:
a first contact electrode in electrical contact with the first electrode and the first end portion of the light-emitting element; and
a second contact electrode in electrical contact with the second electrode and the second end portion of the light-emitting element.

3. The display device of claim 2, wherein the first end portion of the light-emitting element overlaps the first contact electrode in the third direction, and
wherein the second end portion of the light-emitting element overlaps the second contact electrode in the third direction.

4. The display device of claim 1, wherein a separation distance between the first electrode and the second electrode is greater than a separation distance between the first inner bank and the second inner bank.

5. The display device of claim 4, wherein the first inner bank includes a first side and a second side that faces the second inner bank, and
wherein the first electrode covers only the first side of the first inner bank.

6. The display device of claim 5, wherein the second electrode covers a first side of the second inner bank that faces the first inner bank, and a second side of the second inner bank.

7. The display device of claim 1, further comprising:
at least one third inner bank between the first inner bank and the second inner bank; and
at least one third electrode between the first electrode and the second electrode on a partial area of the third inner bank.

8. The display device of claim 7, wherein the third inner bank includes a first side facing the first inner bank, and a second side facing the second inner bank, and
wherein the third electrode covers only the first side of the third inner bank.

9. The display device of claim 7, further comprising a third contact electrode on the third electrode, and having a width that is greater than a width of the third electrode.

10. The display device of claim 9, wherein the third contact electrode is in electrical contact with another light-emitting element between the first electrode and the third electrode, and with yet another light-emitting element between the third electrode and the second electrode.

11. The display device of claim 1, further comprising:
a first voltage line on the substrate; and
a first insulating layer covering the first voltage line,
wherein the first inner bank and the second inner bank are directly on the first insulating layer.

12. The display device of claim 11, wherein at least a partial area of the first voltage line overlaps the first inner bank in the third direction, and
wherein a separation distance between the second electrode and the first electrode is greater than a separation distance between the second electrode and the first voltage line.

13. The display device of claim 12, wherein the first inner bank includes:
a first side on which the first electrode is disposed; and
a second side on which the first electrode is not disposed and which overlaps the first voltage line in the third direction.

14. The display device of claim 13, further comprising a second insulating layer covering the second side of the first inner bank and a first side of the second electrode that faces the first electrode,
wherein the light-emitting element is disposed on the second insulating layer.

15. A display device comprising:
a first data conductive layer including:
a first source or drain electrode; and
a second source or drain electrode,
a second data conductive layer disposed on the first data conductive layer and including:
a first voltage line; and
a second voltage line,
an insulating layer covering the second data conductive layer;
a first electrode and a second electrode disposed on the insulating layer and spaced apart from each other and facing each other in a plan view;
a light-emitting element between the first electrode and the second electrode;
a third electrode between the first electrode and the second electrode; and
a third voltage line,
wherein a vertical distance between the first electrode and the second electrode is greater than a vertical distance between the second electrode and the first voltage line, and
wherein a vertical distance between the second electrode and the third electrode is greater than a vertical distance between the second electrode and the third voltage line.

16. The display device of claim 15, further comprising:
a first inner bank disposed on the first insulating layer; and
a second inner bank that is spaced apart from and faces the first inner bank,
wherein the first electrode covers a first side of the first inner bank, and
wherein the second electrode covers a first side of the second inner bank which faces the first inner bank, and a second side thereof.

17. The display device of claim 16, wherein the first voltage line overlaps a second side of the first inner bank which faces the second inner bank, in a thickness direction.

18. The display device of claim 16, further comprising:
a first contact electrode in electrical contact with the first electrode and a first end portion of the light-emitting element; and
a second contact electrode in electrical contact with the second electrode and a second end portion of the light-emitting element,
wherein the first end portion of the light-emitting element does not overlap the first electrode in a thickness direction, and
wherein the second end portion of the light-emitting element overlaps the second electrode in the thickness direction.

19. The display device of claim 15, wherein the third voltage line is between the first voltage line and the second voltage line.
